(19) United States
(12) Patent Application Publication
(10) Pub. No.: US 2026/0064219 A1
(43) Pub. Date: Mar. 5, 2026

(54) DISPLAY DEVICE

(71) Applicant: LG Display Co., Ltd., Seoul (KR)

(72) Inventors: Hyangmyoung GWON, Paju-si (KR); JiHyun JUNG, Paju-si (KR); JaeGyun LEE, Paju-si (KR); Ruda RHE, Paju-si (KR)

(73) Assignee: LG Display Co., Ltd., Seoul (KR)

(21) Appl. No.: 19/264,667

(22) Filed: Jul. 9, 2025

(30) Foreign Application Priority Data
Aug. 27, 2024 (KR) 10-2024-0114787

(51) Int. Cl. G06F 3/041; G06F 3/044; H10K 59/131; H10K 59/40

(52) U.S. Cl. CPC G06F 3/04164; G06F 3/0412; H10K 59/131; H10K 59/40; G06F 3/044

(57) ABSTRACT

The present disclosure provides a display device including a substrate including a display area and an adjacent non-display area. A plurality of touch electrodes are on the substrate within the display area, and a plurality of touch pads are on the substrate within the non-display area. A plurality of touch routing lines on the substrate to electrically interconnect the touch electrodes and the touch pads. Among the touch routing lines, two adjacent touch routing lines may include a first type touch routing line including one or more touch metal layers and a second type touch routing line including two or more touch metal layers. The number of touch metal layers in the first type touch routing line is less than that of the second type touch routing line, enabling improved resistance balancing and reduced coupling noise, which supports enhanced touch performance and narrow bezel implementation.

### CROSS REFERENCE TO RELATED APPLICATION

This application claims priority from Korean Patent Application No. 10-2024-0114787, filed on Aug. 27, 2024 in the Korean Intellectual Property Office, which is hereby incorporated by reference for all purposes as if fully set forth herein.

### BACKGROUND

### Technical Field

The present disclosure relates to electronic devices, and more specifically, to display devices.

### Description of the Related Art

In today's society, display devices are widely used and increasingly important for presenting images or visual information to users. As needs for providing a user-friendly environment increases, various functions are integrated into the display devices, and many of display devices tend to employ a touch-enabled input interface capable of receiving a touch-based input. Such touch display devices with the touch-enabled input interface allow users to input information or commands more intuitively and conveniently, compared with typical input devices, such as buttons, keyboards, mice, and the like.

These display devices may include a plurality of touch electrodes for touch sensing, and include a plurality of touch routing lines for connecting the plurality of touch electrodes to pads. The plurality of touch routing lines may be disposed in a non-display area of the display devices, and this configuration causes the size of the non-display area to increase.

### BRIEF SUMMARY

To address this issue, one or more aspects of the present disclosure may provide a display device including a touch routing line structure capable of enabling the display device to have a narrow bezel.

For example, the disclosed display device features a touch routing line structure in which adjacent routing lines are formed with different numbers of touch metal layers. This configuration helps balance electrical resistance between lines and reduce coupling noise, supporting narrower bezel designs without degrading touch performance. The routing lines are arranged to extend along inclined surfaces or over dam structures, making efficient use of the non-display area and improving robustness to display noise.

The device also uses mesh type touch electrodes that are positioned to avoid overlapping with light emitting areas, preserving display brightness and efficiency. The substrate includes multiple layers such as polyimide and inorganic insulating layers, which help block moisture and protect against charge interference to improve transistor stability. The design supports the use of both low temperature polysilicon and oxide semiconductor transistors, offering improved performance and greater design flexibility.

One or more aspects of the present disclosure may provide a display device including a touch routing line structure capable of enabling the display device to have a narrow bezel and improving the quality of touch driving and touch sensing.

One or more aspects of the present disclosure may provide a display device including a touch routing line structure capable of reducing a difference in resistance between two adjacent touch routing lines while reducing an interval between two adjacent touch routing lines.

One or more aspects of the present disclosure may provide a display device including a touch routing line structure capable of reducing coupling noise between touch channels.

One or more aspects of the present disclosure may provide a display device including a touch routing line structure capable of reducing a difference in resistance between touch channels.

One or more aspects of the present disclosure may provide a display device including touch routing lines disposed in a structure of being robust to display noise.

According to one or more example embodiments of the present disclosure, a display device can be provided that includes a substrate including a display area and a non-display area adjacent to the display area, a plurality of touch electrodes disposed on the substrate and located in the display area, a plurality of touch pads disposed on the substrate and located in the non-display area, and a plurality of touch routing lines disposed on the substrate and electrically interconnecting the plurality of touch electrodes and the plurality of touch pads.

In one or more aspects, two adjacent touch routing lines among the plurality of touch routing lines may include a first type touch routing line including one or more touch metal layers and a second type touch routing line including two or more touch metal layers.

In one or more aspects, the number of the one or more touch metal layers included in the first type touch routing line may be less than the number of the two or more touch metal layers included in the second type touch routing line.

According to one or more example embodiments of the present disclosure, a display device can be provided that includes a substrate including a display area and a non-display area adjacent to the display area, a plurality of touch electrodes disposed on the substrate and located in the display area, and a plurality of touch routing lines disposed on the substrate and electrically connected to the plurality of touch electrodes.

In one or more aspects, the plurality of touch routing lines may include a first type touch routing line including a touch metal layer not included in the plurality of touch electrodes.

According to one or more aspects of the present disclosure, a display device may be provided that includes a touch routing line structure capable of enabling the display device to have a narrow bezel.

According to one or more aspects of the present disclosure, a display device may be provided that includes a touch routing line structure capable of enabling the display device to have a narrow bezel and improving the quality of touch driving and touch sensing.

According to one or more aspects of the present disclosure, a display device may be provided that includes a touch routing line structure capable of reducing a difference in resistance between two adjacent touch routing lines while reducing an interval between two adjacent touch routing lines.

According to one or more aspects of the present disclosure, a display device may be provided that includes a touch routing line structure capable of reducing coupling noise between touch channels.

According to one or more aspects of the present disclosure, a display device may be provided that includes a touch routing line structure capable of reducing a difference in resistance between touch channels.

According to one or more aspects of the present disclosure, a display device may be provided that includes touch routing lines disposed in a structure of being robust to display noise.

According to one or more aspects of the present disclosure, a display device may be provided that is capable of reducing the size of a bezel of the display device, and thereby, capable of meeting size requirements on the design of the display device and helping the display device be lighter.

### BRIEF DESCRIPTION OF THE SEVERAL VIEWS OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 illustrates an example system configuration of a display device according to aspects of the present disclosure;

FIG. 2 illustrates an example configuration of the display device according to aspects of the present disclosure;

FIG. 3 is an example cross-sectional view of the display panel according to aspects of the present disclosure;

FIG. 4 is an example plan view of the display panel according to aspects of the present disclosure;

FIGS. 5 and 6 illustrate example touch sensor structures included in the display device according to aspects of the present disclosure;

FIG. 7 illustrates an example area of the display panel according to aspects of the present disclosure;

FIGS. 8 to 10 illustrate example touch routing line structures in the display panel according to aspects of the present disclosure;

FIGS. 11 and 12 are a plan view and a cross-sectional view for explaining an example first type touch routing line structure in the display panel according to aspects of the present disclosure; and

FIGS. 13 and 14 are a plan view and a cross-sectional view for explaining an example second type touch routing line structure in the display panel according to aspects of the present disclosure.

### DETAILED DESCRIPTION

Reference will now be made in detail to example embodiments of the present disclosure, examples of which may be illustrated in the accompanying drawings. In the following description, the structures, embodiments, implementations, methods and operations described herein are not limited to the specific example or examples set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Where the terms “comprise,” “have,” “include,” “contain,” “constitute,” “make up of,” “formed of,” and the like are used, one or more other elements may be added unless the term, such as “only,” is used. An element described in the singular form is intended to include a plurality of elements, and vice versa, unless the context clearly indicates otherwise.

Although the terms “first,” “second,” “A,” “B,” “(a),” or “(b),” and the like may be used herein to describe various elements, these elements should not be interpreted to be limited by these terms as they are not used to define a particular order or precedence. These terms are used only to distinguish one element from another; thus, related elements should not be interpreted to be limited by these terms as they are not used to define a particular order or precedence. Further, the expression of a first element, a second elements “and/or” a third element should be understood as one of the first, second and third elements or as any or all combinations of the first, second and third elements. By way of example, A, B and/or C can refer to only A, only B, or only C; any or some combination of A, B, and C; or all of A, B, and C.

For the expression that an element or layer is “connected,” “coupled,” or “adhered” to another element or layer, the element or layer can not only be directly connected, coupled, or adhered to another element or layer, but also be indirectly connected, coupled, or adhered to another element or layer with one or more intervening elements or layers “disposed” or “interposed” between the elements or layers, unless otherwise specified. Further, the another element may be included in one or more of the two or more elements connected, combined, coupled, or contacted (to) one another.

To further elaborate, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

For the expression that an element or layer “contacts,” “overlaps,” or the like with another element or layer, the element or layer can not only directly contact, overlap, or the like with another element or layer, but also indirectly contact, overlap, or the like with another element or layer with one or more intervening elements or layers “disposed” or “interposed” between the elements or layers, unless otherwise specified.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference. In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used. In construing an element, the element is to be construed as including an error or tolerance range even where no explicit description of such an error or tolerance range is provided. Further, the term “may” fully encompasses all the meanings of the term “can.” The term “at least one” should be understood as including any or all combinations of one or more of the associated listed items. For example, the meaning of “at least one of a first element, a second element, and a third element” encompasses the combination of all three listed elements, combinations of any two of the three elements, as well as each individual element, the first element, the second element, and the third element. The expression of a first element, a second elements “and/or” a third element should be understood as one of the first, second and third elements or as any or all combinations of the first, second and third elements. By way of example, A, B and/or C can refer to only A, only B, or only C; any or some combination of A, B, and C; or all of A, B, and C. Hereinafter, various example embodiments of the present disclosure will be described in detail with reference to the accompanying drawings. In addition, for convenience of description, a scale in which each of elements is illustrated in the accompanying drawings may differ from an actual scale. Thus, the illustrated elements are not limited to the specific scale in which they are illustrated in the drawings.

Hereinafter, various example embodiments of the present disclosure will be described in detail with reference to the accompanying drawings. In addition, for convenience of description, a scale in which each of elements is illustrated in the accompanying drawings may differ from an actual scale. Thus, the illustrated elements are not limited to the specific scale in which they are illustrated in the drawings.

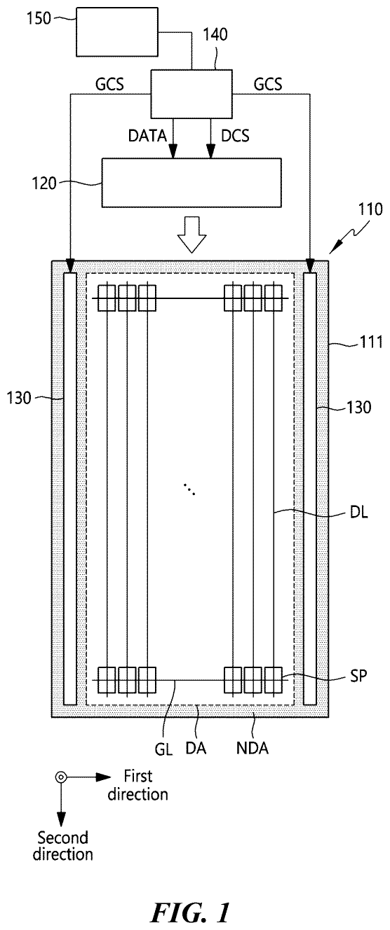

FIG. 1 illustrates an example system configuration of a display device 100 according to aspects of the present disclosure. All components of each display device according to all aspects of the present disclosure are operatively coupled and configured.

Referring to FIG. 1, in one or more example embodiments, the display device 100 may include a display panel 110 and at least one display driving circuit, as elements for display images. The at least one display driving circuit may be one or more circuits for driving the display panel 110. For example, the at least one display driving circuit may include a data driving circuit 120, a gate driving circuit 130, a controller 140, and other circuit components, but aspects of the present disclosure are not limited thereto.

The display panel 110 may include a substrate 111 and a plurality of subpixels SP disposed on the substrate 111.

The substrate 111 may include a display area DA and a non-display area NDA.

The display area DA may be an area allowing an image to be displayed, and also be referred to as an active area. A plurality of subpixels SP for image displaying may be disposed in the display area DA. The non-display area NDA may be an area where an image is not displayed, and be an area outside of the display area DA. The non-display area NDA may also be a non-active area, a bezel area, or a bezel. The non-display area NDA may include a pad area (which may be also referred to as a pad section).

For example, the non-display area NDA may include a first non-display area adjacent to the display area DA, a second non-display area including the pad area, and a bending area between the first non-display area and the second non-display area.

At least one driving circuit may be connected or bonded to the pad area. As the bending area is bent, the bending area and the second non-display area may be located under the first non-display area and thus, be invisible in front of the display device 100. The first non-display area may have a very small size. However, aspects of the present disclosure are not limited thereto.

In one or more aspects, when a user views the display device 100 in front thereof, all or most of the non-display area NDA may be invisible to the user, but aspects of the present disclosure are not limited thereto.

In one or more aspects, the display device 100 may be a self-emission display device in which light is emitted from the display panel 110 itself, but aspects of the present disclosure are not limited thereto. In an example where the display device 100 is the self-emission display device, each of a plurality of subpixels SP included in the display panel 110 may include a light emitting element.

For example, the display device 100 according to aspects of the present disclosure may be an organic light emitting display device in which light emitting elements are implemented using organic light emitting diodes (OLED). In another example, the display device 100 according to aspects of the present disclosure may be an inorganic light emitting display device in which light emitting elements are implemented using inorganic material-based light emitting diodes. In another example, the display device 100 according to aspects of the present disclosure may be a quantum dot display device in which light emitting elements are implemented using quantum dots, which are self-emission semiconductor crystals. In another example, the display device 100 according to aspects of the present disclosure may be a micro LED display device, a mini LED display device, or the like.

The structure of each of a plurality of subpixels SP included in the display panel 110 may depend on types of display device 100. For example, in an example where the display device 100 is a self-emission display device including self-emission subpixels SP, each subpixel SP may include a self-emission light emitting element, one or more transistors, and one or more capacitors, but aspects of the present disclosure are not limited thereto.

Several types of signal lines for driving a plurality of subpixels SP may be disposed on the substrate 111 of the display panel 110. For example, the several types of signal lines may include a plurality of data lines DL for delivering data signals (which may be referred to as data voltages or image signals) to a plurality of subpixels SP, a plurality of gate lines GL for delivering gate signals (which may be referred to as scan signals) to the plurality of subpixels SP, and the like.

For example, the plurality of data lines DL and the plurality of gate lines GL may intersect each other. Each of the plurality of gate lines GL may extend in a first direction (e.g., a row or column direction). Each of the plurality of data lines DL may extend in a second direction (e.g., the column or row direction) different from the first direction.

For example, the first direction may be the row direction, and the second direction may be the column direction. In another example, the first direction may be the column direction, and the second direction may be the row direction. Herein, the row direction and the column direction may not absolute directions, but relative directions. For example, the column direction may be the row direction and the row direction may be the column direction depending on a direction at which the display device 100 or the display panel 110 is viewed. Hereinafter, for convenience of explanation, discussions may be provided based on examples where each of a plurality of data lines DL is disposed in the column direction, and each of a plurality of gate lines GL is disposed in the row direction, but aspects of the present disclosure are limited thereto. Herein, an angle between the first direction and the second direction may be vertical (or 90 degrees) or an angle different from the vertical.

The data driving circuit 120 may be a circuit for driving a plurality of data lines DL and can output data signals to the plurality of data lines DL.

The data driving circuit 120 can receive image data DATA in digital form from the controller 140, convert the received image data DATA into data signals in analog form, and output the resulting data signals to the plurality of data lines DL.

For example, the data driving circuit 120 may be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique. However, aspects of the present disclosure are not limited thereto.

In one or more aspects, the data driving circuit 120 may be located in, and/or electrically connected to, but not limited to, only one side or edge (e.g., an upper portion or a lower portion) of the display panel 110. In one or more aspects, the data driving circuit 120 may be disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The data driving circuit 120 may be connected to an area located outside of the display area DA of the display panel 110, or be disposed in the display area DA of the display panel 110.

The gate driving circuit 130 may be a circuit for driving a plurality of gate lines GL and can supply gate signals to the plurality of gate lines GL.

The gate driving circuit 130 can receive several types of gate driving control signals GCS, and a first gate voltage corresponding to a turn-on voltage (or a turn-on level voltage) and a second gate voltage corresponding to a turn-off voltage (or a turn-off level voltage). Thereby, the gate driving circuit 130 can generate a gate signal including a period with the first gate voltage and a period with the second gate voltage during a certain period of time (e.g., a period of one frame time or a sub-period of the period of one frame time), and supply the generated gate signals to the plurality of gate lines GL. For example, the turn-on level voltage may be a high level voltage and the turn-off level voltage may be a low level voltage. In another example, the turn-on level voltage may be a low level voltage and the turn-off level voltage may be a high level voltage.

In one or more aspects, the gate driving circuit 130 included in the display device 100 may be embedded into the display panel 110 by a gate-in-panel (GIP) technique, but aspects of the present disclosure are not limited thereto. In an example where the gate driving circuit 130 is implemented by the gate-in-panel (GIP) technique, the gate driving circuit 130 may be disposed on the substrate 111 of the display panel 110 during the process of manufacturing the display panel 110 or display device 100. Herein, the gate driving circuit 130 embedded in the display panel 110 by the gate-in-panel (GIP) technique may also be referred to as a “gate-in-panel circuit.”

For example, the gate driving circuit 130 may be disposed in the non-display area NDA of the display panel 110. In another example, the gate driving circuit 130 may be disposed in the display area DA of the display panel 110. In one or more aspects, the gate driving circuit 130 may be disposed in, and/or electrically connected to, but not limited to, a first partial area (e.g., a left portion or a right portion) in the display area DA of the display panel 110. In one or more aspects, the gate driving circuit 130 may be disposed in, and/or electrically connected to, but not limited to, a first partial area (e.g., a left portion or a right portion) in the display area DA, and a second partial area (e.g., the right portion or the left portion) in the display area DA. In one or more aspects, the gate driving circuit 130 may be disposed in all or one or more of areas of the display area DA.

In an example where the gate driving circuit 130 is disposed in the display area DA of the display panel 110, the gate driving circuit 130 may vertically overlap with one or more subpixels SP disposed in the display area DA. For example, the gate driving circuit 130 may vertically overlap with one or more light emitting elements and one or more transistors included in one or more subpixels SP disposed in the display area DA. The gate driving circuit 130 may vertically overlap with the plurality of light emitting elements and a plurality of transistors included in a plurality of subpixels SP disposed in the display area DA. The gate driving circuit 130 may include a plurality of transistors. Each of the plurality of transistors included in the gate driving circuit 130 may include an active layer including a first semiconductor material, and each of the plurality of transistors included in the subpixels SP may include an active layer including a second semiconductor material. For example, the first semiconductor material and the second semiconductor material may be substantially the same. In another example, the first semiconductor material and the second semiconductor material may be different from each other. For example, the first semiconductor material may be a silicon-based semiconductor material (e.g., a low temperature poly silicone (LTPS)), and the second semiconductor material may be an oxide semiconductor material. For example, the active layer may be a semiconductor layer, but aspects of the present disclosure are not limited thereto.

The controller 140 may be a device for controlling the data driving circuit 120 and the gate driving circuit 130, and can control driving timing for a plurality of data lines DL and driving timing for a plurality of gate lines GL.

The controller 140 can supply a data control signal DCS to the data driving circuit 120 to control the data driving circuit 120, and supply a gate control signal GCS to the gate driving circuit 130 to control the gate driving circuit 130.

The controller 140 can receive image data input from a host system 150 and supply image data DATA readable by the data driving circuit 120 based on the input image data to the data driving circuit 120.

The controller 140 may be implemented in a separate component from the data driving circuit 120, or integrated with the data driving circuit 120, so that the controller 140 and the data driving circuit 120 can be implemented in a single integrated circuit.

The controller 140 may be a timing controller used in the typical display technology or a control apparatus/device capable of additionally performing other control functionalities in addition to the typical function of the timing controller. In one or more embodiments, the controller 140 may be one or more other control circuits different from the timing controller, or a circuit or component in the control apparatus/device. The controller 140 may be implemented using various circuits or electronic components such as an integrated circuit (IC), a field programmable gate array (FPGA), an application specific integrated circuit (ASIC), a processor, and/or the like. However, aspects of the present disclosure are not limited thereto.

The controller 140 may be mounted on a printed circuit board, a flexible printed circuit, or the like, and may be electrically connected to the data driving circuit 120 and the gate driving circuit 130 through the printed circuit board, the flexible printed circuit, and/or the like.

The controller 140 can transmit signals to, and receive signals from, the data driving circuit 120 via one or more predetermined interfaces. For example, such interfaces may include a low voltage differential signaling (LVDS) interface, an embedded clock point-point interface (EPI), a serial peripheral interface (SPI), and the like. However, aspects of the present disclosure are not limited thereto.

In one or more aspects, in addition to an image display function, the display device 100 can provide a touch sensing function of detecting the presence or absence of a touch by an object such as a finger, a pen, or the like, or a location of the touch.

In one or more aspects, the display device 100 may be a mobile terminal such as a smart phone, a tablet, or the like, or a monitor, a television (TV), or the like. Such devices may be of various types, sizes, and shapes. The display device 100 according to aspects of the present disclosure is not limited thereto. For example, the display device 100 may include displays of various types, sizes, and shapes for displaying information or images.

In one or more aspects, the display device 100 may further include an electronic device such as a camera (e.g., an image sensor), an electronic unit or device such as a sensor capable of detecting an object, ambient light, etc., and the like. For example, the sensor may be a sensor capable of detecting an object or a human body by receiving light such as infrared light, ultrasonic light, ultraviolet light or the like. However, aspects of the present disclosure are not limited thereto.

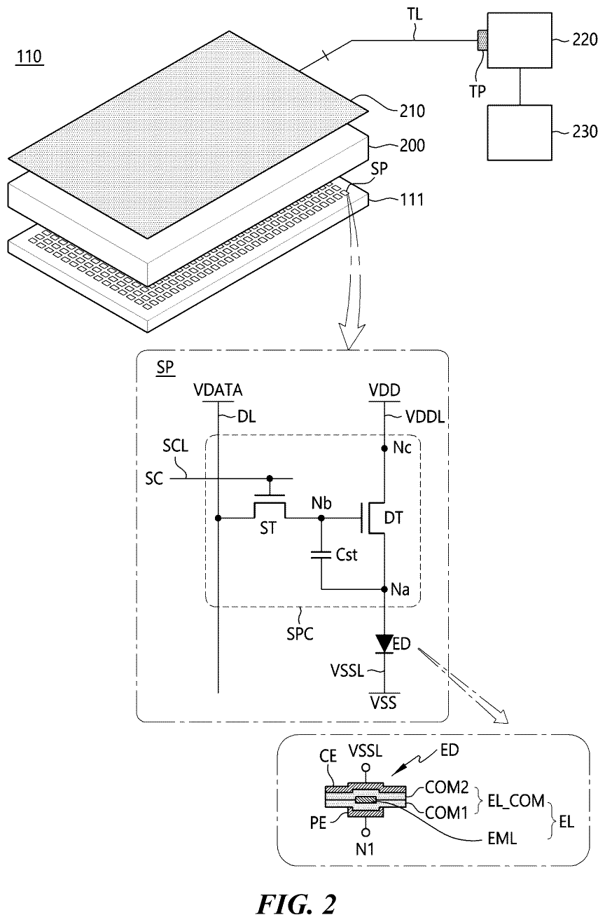

FIG. 2 illustrates an example configuration of the display device 100 according to aspects of the present disclosure.

Referring to FIG. 2, in one or more example embodiments, the display panel 110 may include a substrate 111 on which a plurality of subpixels SP are disposed, and an encapsulation layer 200 over the substrate 111. The encapsulation layer 200 may also be referred to as an encapsulation substrate or an encapsulation stack.

Referring to FIG. 2, in an example where the display device 100 is a self-emission display device, each of the plurality of subpixels SP disposed on the substrate 111 may include a light emitting element ED and a subpixel circuit SPC for driving the light emitting element ED.

Referring to FIG. 2, the subpixel circuit SPC may include a plurality of transistors and at least one capacitor for driving the light emitting element ED, but aspects of the present disclosure are not limited thereto. The subpixel circuit SPC can drive the light emitting element ED by supplying a driving current to the light emitting element ED at a predetermined timing. The light emitting element ED can emit light by being driven by the driving current.

The plurality of transistors may include a driving transistor DT for driving the light emitting element ED and a scan transistor ST configured to be turned on or off by a scan signal SC.

The driving transistor DT can supply a driving current to the light emitting element ED. The scan transistor ST may be configured to control an electrical state of a corresponding node in the subpixel circuit SPC or to control the state or operation of the driving transistor DT. The at least one capacitor may include a storage capacitor Cst configured to maintain a voltage at a constant level during a display frame or a certain period of the display frame.

To drive one or more subpixels SP, at least one data signal VDATA, which is an image signal, and at least one scan signal SC, which is a gate signal, may be applied to the one or more subpixels SP. Further, to drive one or more subpixels SP, common driving signals including a driving voltage VDD and a base voltage VSS may be supplied to the one or more subpixels SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed for each subpixel SP, and the common electrode CE may be an electrode commonly disposed in all or some of a plurality of subpixels SP. For example, the pixel electrode PE may be an anode, and the common electrode CE may be a cathode. In another example, the pixel electrode PE may be a cathode, and the common electrode CE may be an anode. Hereinafter, for convenience of explanation, discussions may be provided based on examples where the pixel electrode PE is an anode, and the common electrode CE is a cathode.

In an example where the light emitting element ED is an organic light emitting diode, the intermediate layer EL may include an emission layer EML, a first common intermediate layer COM1 between the pixel electrode PE and the emission layer EML, and a second common intermediate layer COM2 between the emission layer EML and the common electrode CE. A layer including the first common intermediate layer COM1 and the second common intermediate layer COM2 may be referred to as a common intermediate layer EL_COM.

The emission layer EML may be disposed for each subpixel SP, or be commonly disposed across all or some of a plurality of subpixels SP. The common intermediate layer EL_COM may be commonly disposed across all or some of a plurality of subpixels SP, but aspects of the present disclosure are not limited thereto.

The emission layer EML may be disposed for each light emitting area, or be commonly disposed across all or some of a plurality of light emitting areas. The common intermediate layer EL_COM may be commonly disposed across all or some of a plurality of light emitting areas and a non-light emitting area, but aspects of the present disclosure are not limited thereto.

For example, the first common intermediate layer COM1 may include a hole injection layer (HIL), an electron blocking layer (EBL), a hole transfer layer (HTL), and the like, but aspects of the present disclosure are not limited thereto. The second common intermediate layer COM2 may include an electron transfer layer (ETL), a hole blocking layer (HBL), an electron injection layer (EIL), and the like, but aspects of the present disclosure are not limited thereto.

The hole injection layer can inject holes from the pixel electrode PE to the hole transport layer, the hole transport layer can transport holes to the emission layer EML, the electron injection layer can inject electrons from the common electrode CE to the electron transport layer, and the electron transport layer can transport electrons to the emission layer EML.

For example, the common electrode CE may be electrically connected to a base voltage line VSSL. A base voltage VSS, which is a type of common voltage, may be applied to the common electrode CE through a base voltage line VSSL. The pixel electrode PE may be electrically connected directly or indirectly (via another transistor) to a first node N1 of the corresponding driving transistor DT of each subpixel SP. Herein, the base voltage VSS may also be referred to as a first common voltage, a low power supply voltage, or a low voltage, and the base voltage line VSSL may also be referred to as a first common voltage line, a low power supply voltage line, or a low voltage line.

Each light emitting element ED may be configured by overlapping of a pixel electrode PE, an emission layer EML in an intermediate layer EL, and a common electrode CE. A corresponding light emitting area may be formed by each light emitting element ED. For example, a corresponding light emitting area of each light emitting element ED may include an area where a pixel electrode PE, an emission layer EML in an intermediate layer EL, and a common electrode CE overlap with each other

In one or more aspects, each, or one or more, of light emitting elements ED included in the display panel 110 may be an organic light emitting diode (OLED), an inorganic light emitting diode (LED), a quantum dot light emitting element, a micro LED, or a mini LED, but aspects of the present disclosure are not limited thereto. In the example where each light emitting element ED is an organic light emitting diode (OLED), the corresponding intermediate layer EL of each light emitting element ED may be a layer including an organic material.

Referring to FIG. 2, the driving transistor DT may be a transistor configured to supply a driving current to the light emitting element ED. The driving transistor DT may be connected between a driving voltage line VDDL and the light emitting element ED.

The driving transistor DT may include a first node N1, a second node N2, and a third node N3. The first node N1 may be electrically connected to the light emitting element ED. A data signal VDATA may be applied to the second node N2. A driving voltage VDD, which is a type of common voltage, delivered through the driving voltage line VDDL may be applied to the third node N3. The driving transistor DT may be connected to the first node Na and the third node Nc. Herein, the driving voltage VDD may also be referred to as a second common voltage, a high power supply voltage, or a high voltage, and the driving voltage line VDDL may also be referred to as a second common voltage line, a high power supply voltage line, or a high voltage line.

In the driving transistor DT, the second node N2 may be a gate node, the first node N1 may be a source node or a drain node, and the third node N3 may be the drain node or the source node. Hereinafter, for merely convenience of explanation, discussions may be provided based on examples where the first, second, and third nodes (N1, N2, and N3) of the driving transistor DT are source, gate, and drain nodes, respectively. However, aspects of the present disclosure are not limited thereto.

The scan transistor ST included in the subpixel circuit SPC illustrated in FIG. 2 may be a switching transistor for transferring a data signal VDATA, which is an image signal, to the second node N2, which is the gate node of the driving transistor DT.

The scan transistor ST can be turned on or turned off by a scan signal SC, which is a type of gate signal, applied through a scan line SCL, which is a type of gate line GL, and control an electrical connection between the second node N2 of the driving transistor DT and a data line DL. The drain electrode or source electrode of the scan transistor ST may be electrically connected to the data line DL. The source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and the second node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst may be an external capacitor intentionally designed to be located outside of the driving transistor DT, and therefore, be different from an internal capacitor such as a parasitic capacitor (e.g., a Cgs, a Cgd) that may be formed between the first node N1 and the second node N2 of the driving transistor DT. However, aspects of the present disclosure are not limited thereto.

Each of the driving transistor DT and the scan transistor ST may be an n-type transistor or a p-type transistor, but aspects of the present disclosure are not limited thereto. For example, one of the driving transistor DT and the scan transistor ST may be one of an n-type transistor and a p-type transistor.

The display panel 110 may have a top emission structure or a bottom emission structure. In an example where the display panel 110 has the top emission structure, at least a portion of the subpixel circuit SPC may overlap with at least a portion of the light emitting element ED in the vertical direction. In this configuration, the area or size of a corresponding light emitting area can increase, and a corresponding aperture ratio can increase. In an example where the display panel 110 has the bottom emission structure, the subpixel circuit SPC may not overlap with the light emitting element ED in the vertical direction.

As shown in FIG. 2, the subpixel circuit SPC may include two transistors (2T: DT and ST) and one capacitor (1C: Cst) (which may be referred to as a “2T1C structure”), and in some implementations, may further include one or more transistors, and/or further include one or more capacitors.

For example, the subpixel circuit SPC may have an 3T1C structure including 3 transistors and 1 capacitor. In another example, the subpixel circuit SPC may have an 8T1C structure including 8 transistors and 1 capacitor. In another example, the subpixel circuit SPC may have an 6T2C structure including 6 transistors and 2 capacitor. In another example, the subpixel circuit SPC may have an 7T1C structure including 7 transistors and 1 capacitor. However, aspects of the present disclosure are not limited thereto.

The types and number of gate signals supplied to a subpixel SP, and/or the types and number of gate lines connected to the subpixel SP may vary depending on a structure of a corresponding subpixel circuit SPC. Further, the types and number of common driving signals supplied to a subpixel SP may vary depending on a structure of a corresponding subpixel circuit SPC.

Referring to FIG. 2, since circuit elements (e.g., light emitting elements ED such as organic light emitting diodes (OLED) including an organic material) in each subpixel SP are vulnerable to external moisture or oxygen, an encapsulation layer 200 may be disposed in the display panel 110. The encapsulation layer 200 can prevent external moisture or oxygen from penetrating into the circuit elements (e.g., the light emitting elements ED). The encapsulation layer 200 may be disposed in various shapes or configurations to prevent light emitting elements ED from contacting moisture or oxygen. For example, the encapsulation layer 200 may include two or more layers in which one or more organic layers and one or more inorganic layers are alternately stacked, but aspects of the present disclosure are not limited thereto.

Referring to FIG. 2, in one or more aspects, to provide a touch sensing function, the display device 100 may include a touch sensor layer 210 including a plurality of sensor electrodes, and a touch sensing circuit configured to sense a touch sensor disposed in the touch sensor layer 210 and determine whether a touch is applied or a location of the touch (e.g., touch coordinates). The touch sensor layer 210 may also be called a touch part or a touch sensing part.

For example, the touch sensing circuit may include a touch driving circuit 220 configured to drive and sense the touch sensor disposed in the touch sensor layer 210 to generate and output touch sensing data, and a touch controller 230 configured to determine the presence or absence of a touch or touch coordinates based on the touch sensing data from the touch driving circuit 220.

The touch sensor layer 210 may be a layer where the touch sensor is formed, and the touch sensor may be configured with a plurality of touch electrodes.

For example, the touch sensor layer 210 may be disposed outside of the display panel 110 and be disposed in a separate touch panel different from the display panel 110. In this example, the touch panel and the display panel 110 may be manufactured separately and combined during the assembly process.

In another example, the touch sensor layer 210 may be embedded into the display panel 110. When the touch sensor layer 210 is embedded inside of the display panel 110, the touch sensor layer 210 may be disposed on the substrate 111 together with signal lines and electrodes related to display driving during the process of manufacturing the display panel 110. For example, the touch sensor layer 210 may be disposed on the encapsulation layer 200. Hereinafter, for convenience of explanation, discussions are provided for examples in which the touch sensor layer 210 is embedded into the display panel 110.

In the example where the touch sensor layer 210 is embedded inside of the display panel 110, in addition to the plurality of touch electrodes serving as the touch sensor, the display panel 110 may further include a plurality of touch pads TP to which the touch driving circuit 220 is electrically connected, and a plurality of touch routing lines for electrically interconnecting the plurality of touch electrodes and the plurality of touch pads TP. The plurality of touch routing lines TL may also be referred to as a plurality of touch lines. The plurality of touch routing lines TL may correspond to a plurality of touch channels.

The touch driving circuit 220 can supply a touch driving signal to at least one of the plurality of touch electrodes, sense at least one of the plurality of touch electrodes, and generate touch sensing data based on the result of the sensing.

The touch sensing circuit can perform touch sensing by a self-capacitance sensing technique or a mutual-capacitance sensing technique.

In the example where the touch sensing circuit performs touch sensing by the self-capacitance sensing technique, the touch sensing circuit can perform touch sensing based on capacitance between each touch electrode and a touch object (e.g., a finger, a pen, and the like). According to the self-capacitance sensing, each of a plurality of touch electrodes may serve as both a driving touch electrode and a sensing touch electrode. The touch driving circuit may drive all, or one or more, of the plurality of touch electrodes and sense all, or one or more, of the plurality of touch electrodes.

In the example where the touch sensing circuit performs touch sensing by the mutual-capacitance sensing technique, the touch sensing circuit can perform touch sensing based on a capacitance between touch electrodes (e.g., two adjacent touch electrodes). According to the mutual-capacitance sensing, a plurality of touch electrodes may be divided into driving touch electrodes and sensing touch electrodes. The touch driving circuit can drive the driving touch electrodes and sense the sensing touch electrodes. Touch routing lines connected to the driving touch electrodes may be referred to as driving touch routing lines, and touch routing lines connected to the sensing touch electrodes may be referred to as sensing touch routing lines.

In one or more aspects, the touch driving circuit 220 and the touch controller 230 may be implemented in separate devices or in one device. In one or more aspects, the touch driving circuit 220 and the data driving circuit 120 may be implemented in separate devices or in one device.

The display device 100 may further include a power supply circuit for supplying several types of power to the display driving circuit and/or the touch sensing circuit. The power supply circuit can supply several types of voltages and power supply voltages related to display driving to the display driving circuit or display panel 110.

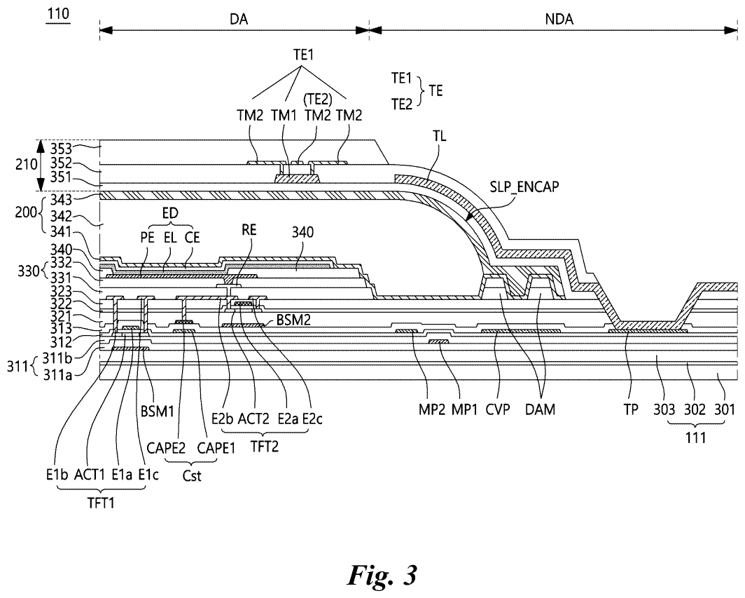

FIG. 3 is an example cross-sectional view of the display panel 110 according to aspects of the present disclosure.

Referring to FIG. 3, in one or more example embodiments, the display panel 110 may include a substrate 111, a transistor part, a light emitting element part, and an encapsulation part, but aspects of the present disclosure are not limited thereto.

A substrate 111 may be in the form of a single layer or multilayer. In an example where the substrate 111 is in the formed of a multilayer, the substrate 111 may include a first substrate 301, an intermediate substrate layer 302, and a second substrate 303. The intermediate substrate layer 302 may be located between the first substrate 301 and the second substrate 303. For example, each of the first substrate 301 and the second substrate 303 may be a polyimide (PI) layer, but aspects of the present disclosure are not limited thereto. The intermediate substrate layer 302 may be an inorganic insulating layer, but aspects of the present disclosure are not limited thereto. When charges are stored in the first substrate 301, which is the polyimide layer, the intermediate substrate layer 302 can block the charges from affecting one or more transistors disposed on the second substrate 303 through the second substrate 303, which is the polyimide layer.

In addition, the intermediate substrate layer 302 can block moisture from penetrating upwardly through the first substrate 301. For example, the intermediate substrate layer 302 may be in the form of a single layer of silicon nitride (SiNx) or silicon oxide (SiOx) or a multilayer thereof, or may be in the form of a double layer of silicon dioxide (SiO2) and silicon nitride (SiNx). However, aspects of the present disclosure are not limited thereto.

The transistor part may include insulating layers (311, 312, 313, 321, 322, and 323), thin film transistors (TFT1 and TFT2), a storage capacitor Cst, and several electrodes or signal lines, which are disposed on the substrate 111.

The thin film transistors (TFT1 and TFT2) included in the transistor part may include a first thin film transistor TFT1 and a second thin film transistor TFT2.

The first thin film transistor TFT1 may include a first active layer ACT1, a first electrode E1a, a second electrode E1b, and a third electrode E1c.

The first electrode E1a may be a gate electrode, the second electrode E1b may be a source electrode or a drain electrode, and the third electrode E1c may be the drain electrode or the source electrode. Hereinafter, for convenience of explanation, discussions may be provided based on examples where the first, second, and third electrodes (E1a, E1b, and E1c) are a first gate electrode E1a, a first source electrode E1b, and a first drain electrode E1c, respectively. However, aspects of the present disclosure are not limited thereto.

The first active layer ACT1 may include a first semiconductor material. For example, the first semiconductor material may include an oxide semiconductor, amorphous silicon, polysilicon, low-temperature polysilicon (LTPS), or the like, but aspects of the present disclosure are not limited thereto. The first thin film transistor TFT1 may be a p-channel transistor or an n-channel transistor, but aspects of the present disclosure are not limited thereto.

The second thin film transistor TFT2 may include a second active layer ACT2, a fourth electrode E2a, a fifth electrode E2b, and a sixth electrode E2c.

The fourth electrode E2a may be a gate electrode, the fifth electrode E2b may be a source electrode or a drain electrode, and the sixth electrode E2c may be the drain electrode or the source electrode. Hereinafter, for convenience of explanation, discussions may be provided based on examples where the fourth, fifth, and sixth electrodes (E2a, E2b, and E2c) are a second gate electrode E2a, a second source electrode E2b, and a second drain electrode E2c, respectively. However, aspects of the present disclosure are not limited thereto.

The second active layer ACT2 may include a second semiconductor material. For example, the second semiconductor material may include an oxide semiconductor, amorphous silicon, polysilicon, low-temperature polysilicon (LTPS), or the like, but aspects of the present disclosure are not limited thereto. The second thin film transistor TFT2 may be a p-channel transistor or an n-channel transistor, but aspects of the present disclosure are not limited thereto.

Semiconductor materials of each of the first active layer ACT1 of the first thin film transistor TFT1 and the second active layer ACT2 of the second thin film transistor TFT2 may be as follows.

For example, the first active layer ACT1 of the first thin film transistor TFT1 and the second active layer ACT2 of the second thin film transistor TFT2 may include an oxide semiconductor material. In another example, the first active layer ACT1 of the first thin film transistor TFT1 and the second active layer ACT2 of the second thin film transistor TFT2 may include a low-temperature polysilicon semiconductor material. In another example, the first active layer ACT1 of the first thin film transistor TFT1 may include a low-temperature polysilicon semiconductor material, and the second active layer ACT2 of the second thin film transistor TFT2 may include an oxide semiconductor material. In another example, the first active layer ACT1 of the first thin film transistor TFT1 may include an oxide semiconductor material, and the second active layer ACT2 of the second thin film transistor TFT2 may include a low-temperature polysilicon semiconductor material.

Transistors included in the display area DA may be used as follows.

For example, all transistors included in each subpixel SP may be implemented as the first thin film transistor TFT1. In another example, all transistors included in each subpixel SP may be implemented as the second thin film transistor TFT2. In another example, one or more of all transistors included in each subpixel SP may be implemented as the first thin film transistor TFT1, and one or more of the remaining one or more transistors may be implemented as the second thin film transistor TFT2. For example, each subpixel SP may include at least one first thin film transistor TFT1 and at least one second thin film transistor TFT2.

In the example where one or more of all transistors included in each subpixel SP are implemented as a first thin film transistor TFT1, and one or more of the remaining one or more transistors are implemented as a second thin film transistor TFT2, the following specific examples may be implemented in the display panel 110.

For example, in each subpixel SP, a driving transistor DT may be implemented as the first thin film transistor TFT1, and one or more transistors (e.g., a scan transistor ST, an emission control transistor, and the like) different from the driving transistor DT may be implemented as the second thin film transistor TFT2.

For example, in each subpixel SP, a driving transistor DT may be implemented as the second thin film transistor TFT2, and one or more transistors (e.g., a scan transistor ST, an emission control transistor, and the like) different from the driving transistor DT may be implemented as the first thin film transistor TFT1.

In FIG. 3, the second thin film transistor TFT2 connected to a pixel electrode PE of a light emitting element ED may be a driving transistor DT or a transistor different from the driving transistor DT depending on the configuration of a corresponding subpixel circuit SPC. For example, in FIG. 3, the second thin film transistor TFT2 connected to the pixel electrode PE of the light emitting element ED may be an emission control transistor connected between a driving transistor DT and the light emitting element ED.

Transistors disposed in the non-display area NDA may be uses as follows.

For example, active layers of transistors included in the gate driving circuit 130 of the gate-in-panel (GIP) type may include an oxide semiconductor material. In another example, the active layers of the transistors included in the gate driving circuit 130 of the gate-in-panel (GIP) type may include a low-temperature polysilicon semiconductor material. In another example, among active layers of transistors included in the gate driving circuit 130 of the gate-in-panel (GIP) type, one or more active layers may include a low-temperature polysilicon semiconductor material, and the remaining one or more active layers may include an oxide semiconductor material.

Referring to FIG. 3, the second active layer ACT2 of the second thin film transistor TFT2 may be located higher from the substrate 111 than the first active layer ACT1 of the first thin film transistor TFT1.

A first buffer layer 311 may be disposed under the first active layer ACT1 of the first transistor TFT1, and a second buffer layer 321 may be disposed under the second active layer ACT2 of the second transistor TFT2. For example, the first active layer ACT1 of the first thin film transistor TFT1 may be located on the first buffer layer 311, and the second active layer ACT2 of the second thin film transistor TFT2 may be located on the second buffer layer 321. The second buffer layer 321 may be located higher from the substrate 111 than the first buffer layer 311.

The storage capacitor Cst may be disposed in several metal layers in the display panel 110. For example, the storage capacitor Cst may include a first capacitor electrode CAPE1 and a second capacitor electrode CAPE2.

The light emitting element part may include a plurality of light emitting elements ED disposed on at least one planarization layer 330. Each of the light emitting elements ED may include a pixel electrode PE, an intermediate layer EL, and a common electrode CE.

The encapsulation part may include an encapsulation layer 200 on the plurality of light emitting elements ED. The encapsulation layer 200 may be in the form of a single layer or multilayer, but aspects of the present disclosure are not limited thereto. In addition to the encapsulation layer 200, the encapsulation part may further include at least one dam DAM to prevent a material included in the encapsulation layer 200 from overflowing. For example, when a second encapsulation layer 342 included in the encapsulation layer 200 is an organic encapsulation layer including an organic material, the dam DAM can prevent the organic material from overflowing.

Hereinafter, the stack-up configuration of the display panel 110 is described in more detail with reference to FIG. 3.

Referring to FIG. 3, the first buffer layer 311 may be disposed on the substrate 111. The first buffer layer 311 may be in the form of a single layer or multilayer. In an example where the first buffer layer 311 is in the form of a multilayer, the first buffer layer 311 may include a lower buffer layer 311a and an upper buffer layer 311b.

The first active layer ACT1 of the first thin film transistor TFT1 may be disposed on the first buffer layer 311. The first active layer ACT1 may include a channel region where a channel is formed, a source connection region on a first side of the channel region, and a drain connection region on a second opposing side of the channel region.

A first gate insulating layer 312 may be disposed on the first active layer ACT1 of the first thin film transistor TFT1. The first gate electrode E1a of the first thin film transistor TFT1 may be disposed on the first gate insulating layer 312. A first interlayer insulating layer 313 may be disposed on the first gate electrode E1a of the first thin film transistor TFT1. A metal layer in which the first gate electrode E1a of the first thin film transistor TFT1 is disposed may be referred to as a first gate metal layer.

The second buffer layer 321 may be disposed on the first interlayer insulating layer 313.

The second active layer ACT2 of the second thin film transistor TFT2 may be disposed on the second buffer layer 321. The second active layer ACT2 may include a channel region where a channel is formed, a source connection region on a first side of the channel region, and a drain connection region on a second opposing side of the channel region.

A second gate insulating layer 322 may be disposed on the second active layer ACT2 of the second thin film transistor TFT2. The second gate electrode E2a of the second transistor TFT2 may be disposed on the second gate insulating layer 322. A second interlayer insulating layer 323 may be disposed on the second gate electrode E2a of the second thin film transistor TFT2. The second gate electrode E2a of the second thin film transistor TFT2 may be referred to as a second gate metal layer.

The first source electrode E1b and the first drain electrode E1c of the first thin film transistor TFT1 and the second source electrode E2b and the second drain electrode E2c of the second thin film transistor TFT2 may be disposed on the second interlayer insulating layer 323.

The first source electrode E1b and the first drain electrode E1c of the first thin film transistor TFT1 may be connected to the source connection region and the drain connection region of the first active layer ACT1 respectively through holes in the second interlayer insulating layer 323, the second gate insulating layer 322, the second buffer layer 321, the first interlayer insulating layer 313, and the first gate insulating layer 312.

The second source electrode E2b and the second drain electrode E2c of the second thin film transistor TFT2 may be connected to the source connection region and drain connection region of the second active layer ACT2 respectively through holes in the second interlayer insulating layer 323 and the second gate insulating layer 322.

The first source electrode E1b and the first drain electrode E1c of the first thin film transistor TFT1, and the second source electrode E2b and the second drain electrode E2c of the second thin film transistor TFT2 may include a first source-drain metal and be disposed in a first source-drain metal layer.

Referring to FIG. 3, in one or more aspects, the storage capacitor Cst may be configured with the first capacitor electrode CAPE1 and the second capacitor electrode CAPE2. In one or more aspects, the storage capacitor Cst may include three or more capacitor electrodes, or may include two or more capacitors connected in parallel.

Each of the first capacitor electrode CAPE1 and the second capacitor electrode CAPE2 may be disposed in several metal layers in the display panel 110.

In one or more aspects, the first capacitor electrode CAPE1 may include the same first gate metal as the first gate electrode E1a of the first thin film transistor TFT1 on the first gate insulating layer 312, and be disposed in the first gate metal layer, but aspects of the present disclosure are not limited thereto. In one or more aspects, the second capacitor electrode CAPE2 may be disposed on the first interlayer insulating layer 313.

The second source electrode E2b of the second thin film transistor TFT2 may be electrically connected to the second capacitor electrode CAPE2 through holes in the second interlayer insulating layer 323, the second gate insulating layer 322, and the second buffer layer 321.

For example, when the stack-up configuration of FIG. 3 is applied to the subpixel circuit of FIG. 2, the first thin film transistor TFT1 may be the scan transistor ST of FIG. 2, and the second thin film transistor TFT2 may be the driving transistor DT of FIG. 2.

The transistor part may further include several metal patterns (e.g., a first metal pattern MP1, a second metal pattern MP2, and the like). For example, the first metal pattern MP1 may be disposed between the lower buffer layer 311a and the upper buffer layer 311b included in the first buffer layer 311, but aspects of the present disclosure are not limited thereto. The second metal pattern MP2 may include the same first gate metal as the first gate electrode E1a of the first thin film transistor TFT1 and be disposed in the first gate metal layer, but aspects of the present disclosure are not limited thereto.

Each of the first metal pattern MP1 and the second metal pattern MP2 may be disposed in the display area DA or the non-display area NDA.

Referring to FIG. 3, the transistor part may further include a first shield pattern BSM1 disposed on the substrate 111. The first shield pattern BSM1 may overlap with the first active layer ACT1 of the first thin film transistor TFT1. The first shield pattern BSM1 may be disposed under the first active layer ACT1 of the first thin film transistor TFT1. For example, the first shield pattern BSM1 may be disposed between the substrate 111 and the first buffer layer 311, or may be disposed between the lower buffer layer 311a and the upper buffer layer 311b.

The transistor part may further include a second shield pattern BSM2 disposed on the substrate 111. The second shield pattern BSM2 may overlap with the second active layer ACT2 of the second thin film transistor TFT2. The second shield pattern BSM2 may be disposed under the second active layer ACT2 of the second thin film transistor TFT2. For example, the second shield pattern BSM2 may be disposed in a metal layer between the first interlayer insulating layer 313 and the second buffer layer 321. The second shield pattern BSM2 may be disposed in the same metal layer as the second capacitor (CAPE2, but aspects of the present disclosure are not limited thereto. In another example, the second shield pattern BSM2 may be disposed in the same first gate metal layer as the first gate electrode E1a of the first thin film transistor TFT1.

Referring to FIG. 3, the transistor part may further include a common driving signal layer CVP to which a common driving voltage is applied. The common driving signal layer CVP may be disposed in the display area DA or the non-display area NDA.

For example, a common driving voltage applied to the common driving voltage pattern CVP may be referred to as a power signal, and for example, include at least one of a driving voltage VDD and a base voltage VSS. The driving voltage VDD may be referred to as a high driving voltage (or a high power supply voltage or a high voltage), and the base voltage VSS may be referred to as a low driving voltage (or a low power supply voltage or a low voltage).

The planarization layer 330 may be disposed on the first thin film transistor TFT1 and the second thin film transistor TFT2, and be disposed under a light emitting element ED. The planarization layer 330 may be an organic insulating layer including an organic insulating material.

For example, the planarization layer 330 may be in the form of a single layer. In another example, the planarization layer 330 may include two layers. The planarization layer 330 may include a first planarization layer 331 and a second planarization layer 332. In one or more aspects, the planarization layer 330 may include three or more layers. However, aspects of the present disclosure are not limited thereto.

Referring to FIG. 3, the first planarization layer 331 may be disposed on the first source electrode E1b and the first drain electrode E1c of the first thin film transistor TFT1 and the second source electrode E2b and the second drain electrode E2c of the second thin film transistor TFT2. For example, the first planarization layer 331 may be disposed on the first thin film transistor TFT1 and the second thin film transistor TFT2. For example, the first planarization layer 331 may be disposed such that it covers both the first thin film transistor TFT1 and the second thin film transistor TFT2.

Referring to FIG. 3, a connection electrode RE may be disposed on the first planarization layer 331. The connection electrode RE may electrically connect the second source electrode E2b of the second thin film transistor TFT2 and a pixel electrode PE.

The connection electrode RE may be electrically connected to the second source electrode E2b of the second thin film transistor TFT2 through a hole of the first planarization layer 331. The second source electrode E2b of the second thin film transistor TFT2 may be electrically connected to the second capacitor electrode CAPE2 of the storage capacitor Cst.

The connection electrode RE may be disposed in a second source-drain metal layer on the first planarization layer 331 and may include a second source-drain metal.

The second planarization layer 332 may be disposed on the connection electrode RE.

Referring to FIG. 3, the light emitting element part may be disposed on the second planarization layer 332. The light emitting element ED may be disposed on the second planarization layer 332. The light emitting element ED may include the pixel electrode PE, an intermediate layer EL, and a common electrode CE. A light emitting area of the light emitting element ED may be formed in an area where the pixel electrode PE, the intermediate layer EL, and the common electrode CE overlap with, and contact, each other.

The pixel electrode PE may be disposed on the second planarization layer 332. The pixel electrode PE may be electrically connected to the connection electrode RE through a hole of the second planarization layer 332.

A bank 340 may be disposed on the pixel electrode PE. An opening of the bank 340 may expose a portion of the pixel electrode PE to form the light emitting area. The opening of the bank 340 may overlap with the portion of the pixel electrode PE.

For example, the bank 340 may include a material including a black pigment, or an organic material including a benzocyclobutene resin, a polyimide resin, an acrylic resin, a photosensitive polymer, or the like, but aspects of the present disclosure are not limited thereto. In an example where the bank 340 includes a material including a black pigment or a black dye, the bank 540 may be a black bank. In the example where the bank 340 includes a material including a black pigment or a black dye, the luminance of the display device 100 can be further improved because light from the outside or light reflected from the outside can be blocked.

The intermediate layer EL of the light emitting element ED may be disposed on a portion of the pixel electrode PE and the bank 340. The common electrode CE may be disposed on the intermediate layer EL.

Referring to FIG. 3, the encapsulation part may be disposed on the light emitting element part, and be located on the common electrode CE. The encapsulation part may include an encapsulation layer 200 disposed on the common electrode CE.

The encapsulation layer 200 can prevent moisture or oxygen from penetrating into the light emitting element ED. For example, the encapsulation layer 200 can prevent moisture or oxygen from penetrating into an organic material included in the intermediate layer EL of the light emitting element ED. In one or more aspects, the encapsulation layer 200 may be in the form of a single layer or multilayer, but aspects of the present disclosure are not limited thereto.

For example, the encapsulation layer 200 may include a first encapsulation layer 341, a second encapsulation layer 342, and a third encapsulation layer 343, but aspects of the present disclosure are not limited thereto. For example, the first encapsulation layer 341 and the third encapsulation layer 343 may be inorganic encapsulation layers, and the second encapsulation layer 342 may include an organic encapsulation layer. However, aspects of the present disclosure are not limited thereto.

In one or more aspects, a touch sensor may be embedded in the display panel 110. In this implementation, the display panel 110 may include a touch sensor layer 210 disposed on the encapsulation layer 200. For example, the touch sensor layer 210 may be a layer in which the touch sensor is disposed.

Referring to FIG. 3, the touch sensor layer 210 may include a plurality of touch electrodes TE serving as the touch sensor, and include at least one touch metal layer for forming the plurality of touch electrodes TE.

For example, to form the plurality of touch electrodes TE, the touch sensor layer 210 may include a first touch metal layer in which a plurality of first touch metals TM1 are disposed, and a second touch metal layer in which a plurality of second touch metals TM2 are disposed. In this implementation, the touch sensor layer 210 may further include a touch interlayer insulating layer 352 disposed between the first touch metal layer and the second touch metal layer.

For example, one of the first touch metal layer and the second touch metal layer may be a sensor metal layer, and the other may be a bridge metal layer.

For example, the first touch metal layer may be a bridge metal layer, and the second touch metal layer may be a sensor metal layer. In this implementation, the plurality of second touch metals TM2 disposed in the second touch metal layer may be sensor metals forming the touch sensor, and the plurality of first touch metals TM1 disposed in the first touch metal layer may be bridge metals electrically connecting the plurality of second touch metals TM2, which are the sensor metals. For example, two or more second touch metals TM2 and at least one first touch metal TM1 may form one first touch electrode TE1. In this implementation, the two or more second touch metals TE2 may be electrically connected by at least one first touch metal TM1.

In another example, the first touch metal layer may be a sensor metal layer, and the second touch metal layer may be a bridge metal layer. In this implementation, the plurality of first touch metals TM1 disposed in the first touch metal layer may be sensor metals forming the touch sensor, and the plurality of second touch metals TM2 disposed in the second touch metal layer may be bridge metals electrically connecting the plurality of first touch metals TM1, which are the sensor metals.

In another example, each of the first touch metal layer and the second touch metal layer may be a sensor metal layer and a bridge metal layer. For example, the first touch metal layer may be a sensor metal layer and a bridge metal layer, and the second touch metal layer may be a sensor metal layer and a bridge metal layer. In this implementation, the plurality of first touch metals TM1 disposed in the first touch metal layer may include sensor metals and bridge metals, and the plurality of second touch metals TM2 disposed in the second touch metal layer may include sensor metals and bridge metals.

Referring to FIG. 3, the touch sensor layer 210 may further include a touch buffer layer 351 disposed on the encapsulation layer 200. The touch buffer layer 351 may be disposed between the encapsulation layer 200 and the touch metal layer. For example, the first touch metal layer may be disposed on the touch buffer layer 351, and the touch interlayer insulating layer 352 may be disposed on the first touch metal layer.

Referring to FIG. 3, the touch sensor layer 210 may further include a touch protection layer 353 disposed such that the touch protection layer 553 covers the touch metal layers. For example, the touch protection layer 353 may be disposed on the second touch metal layer.

For example, the touch buffer layer 351 may be an inorganic layer including an inorganic insulating material or an organic layer including an organic insulating material. The touch interlayer insulating layer 352 may be an inorganic layer including an inorganic insulating material or an organic layer including an organic insulating material. The touch protection layer 353 may be an inorganic layer including an inorganic insulating material or an organic layer including an organic insulating material.

For example, at least one of the touch buffer layer 351 and the touch interlayer insulating layer 352 may be disposed to extend from the display area DA to the non-display area NDA. The touch protection layer 353 may be disposed to extend from the display area DA to the non-display area NDA.

A touch routing line TL may electrically connect a touch electrode TE and a touch pad TP. The touch routing line TL may be formed by at least one of the first touch metal TM1 and the second touch metal TM2.

For example, the touch routing line TL may be formed by the first touch metal TM1. For example, the touch routing line TL may be formed by the second touch metal TM2. For example, the touch routing line TL may be formed by the first touch metal TM1 and the second touch metal TM2. In an example where one touch routing line TL is formed by the first touch metal TM1 and the second touch metal TM2, the first touch metal TM1 and the second touch metal TM2 included in the touch routing line TL may be electrically connected through a hole in the insulating layer 352.

For example, one touch routing line TL may include a plurality of line portions, and each of the plurality of line portions may be a single line portion or a double line portion. Herein, the term “single line portion” may be a line portion with one signal path, and the term “double line portion” may be a line portion with two signal paths connected in parallel.

The touch routing line TL may extend along an inclined surface of the encapsulation layer 200, extend over an upper portion of at least one dam DAM. and reach a touch pad TP.

The touch buffer layer 351 may have an opening to expose at least a portion of the touch pad TP. The touch routing line TL may be electrically connected to the touch pad TP through the opening of the touch buffer layer 351. The touch interlayer insulating layer 352 may be disposed on a portion of the touch routing line TL and may extend to an area where the touch pad TP is disposed. The touch protection layer 353 may be disposed only in the display area DA, or may extend to the non-display area NDA and be disposed on the touch routing line TL. In one or more aspects, the touch protection layer 353 may extend further to an upper portion of the touch pad TP.

Each of a plurality of touch electrodes TE may be a mesh-type electrode configured to have a mesh with a plurality of openings. In this implementation, each of the plurality of touch electrodes TE may include at least one second touch metal TM2. However, aspects of the present disclosure are not limited thereto.

For example, the plurality of touch electrodes TE may include at least one first touch electrode TE1 and at least one second touch electrode TE2. In an example where the first touch metal layer is a bridge metal layer and the second touch metal layer is a sensor metal layer, two or more second touch metals TM2 included in a first touch electrode TE1, which serves as the touch sensor, may be electrically connected through at least one first touch metal TM1, which is the bridge metal. For example, two second touch metals TM2 spaced apart from each other may be electrically connected by a first touch metal TM1 to form one first touch electrode TE1.

Referring to FIG. 3, the plurality of first touch metals TM1 and the plurality of second touch metals TM2 may be disposed not to overlap with the light emitting element ED. The plurality of first touch metals TM1 and the plurality of second touch metals TM2 may overlap with the bank 340. According to these configurations, the display panel 110 can provide an advantage of improving the emission efficiency of the light emitting element ED.

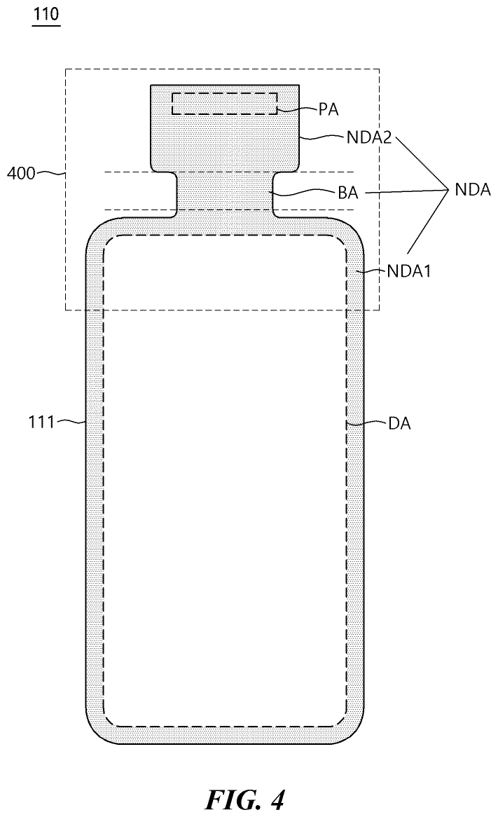

FIG. 4 is an example plan view of the display panel 110 according to aspects of the present disclosure.

Referring to FIG. 4, in one or more example embodiments, the substrate 111 of the display panel 110 may include the display area DA and the non-display area NDA. The display area DA and the non-display area NDA may be areas defined in the display panel 110.

The display area DA may be an area where an image is displayed, and be an area where a plurality of subpixels SP are disposed.

The non-display area NDA may be an area where an image is not displayed, and be an area except for the display area DA. A subpixel SP may not be disposed in the non-display area ND). In one or more aspects, at least one dummy subpixel, which is not directly involved in image displaying, may be disposed in the non-display area NDA.

In one or more aspects, the non-display area NDA may include a first non-display area NDA1, a bending area BA, and a second non-display area NDA2.

The first non-display area NDA1 may be located adjacent to the display area DA, and may be an area located closest to the display area DA among the first non-display area NDA1, the bending area BA, and the second non-display area NDA2.

The second non-display area NDA2 may include a pad area allowing several pads to be disposed and be an area located farthest away from the display area DA among the first non-display area NDA1, the bending area BA, and the second non-display area NDA2.

The bending area BA may be an area allowing the substrate 111 to be bent, and may be located between the first non-display area NDA1 and the second non-display area NDA2.

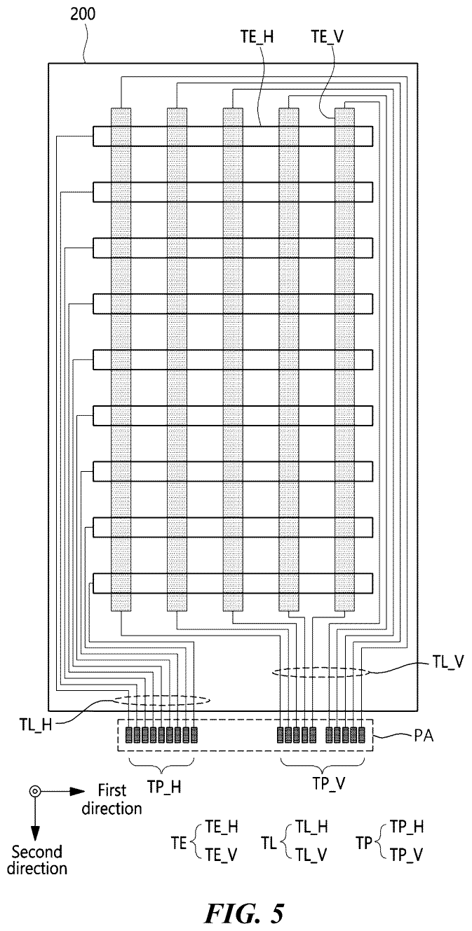

FIG. 5 illustrates an example touch sensor structure included in the display device 100 according to aspects of the present disclosure.

Referring to FIG. 5, in one or more example embodiments, the display panel 110 of the display device 100 may include the substrate 111 including the display area DA and the non-display area NDA surrounding the display area DA, a plurality of touch electrodes TE disposed over the substrate 111 and located in the display area DA, a plurality of touch pads TP disposed on the substrate 111 and located in the non-display area NDA, and a plurality of touch routing lines TL disposed on the substrate 111 and electrically interconnecting the plurality of touch electrodes TE and the plurality of touch pads TP.

In one or more aspects, a touch sensor included in the display device 100 may include the plurality of touch electrodes TE. The plurality of touch electrodes TE may include a plurality of horizontal touch electrodes TE_H and a plurality of vertical touch electrodes TE_V.

The plurality of touch electrodes TE may be located in the display area DA and may be disposed on the encapsulation layer 200.

Each of the plurality of horizontal touch electrodes TE_H may be disposed in a first direction, and each of the plurality of vertical touch electrodes TE_V may be disposed in a second direction different from the first direction.

Herein, the first direction and the second direction may be relatively different directions, and for example, the first direction may be an x-axis direction and the second direction may be a y-axis direction. In another example, the first direction may be the y-axis direction and the second direction may be the x-axis direction. The first direction and the second direction may be orthogonal to each other, or may not be orthogonal. Herein, rows and columns are relatively defined and are interchanged depending on a direction at which the display device 100 or the display panel 110 is viewed. For example, the first direction may be a direction in which gate lines GL extend, and the second direction may be a direction in which data lines DL extend. In another example, the first direction may be a direction in which data lines DL extend, and the second direction may be a direction in which gate lines GL extend.

In one or more aspects, each of the plurality of horizontal touch electrodes TE_H may be a touch electrode having a bar shape, and each of the plurality of vertical touch electrodes TE_V may be a touch electrode having a bar shape. In this implementation, for example, the plurality of horizontal touch electrodes TE_H may be disposed in the first touch metal layer, and the plurality of vertical touch electrodes TE_V may be disposed in the second touch metal layer. In another example, the plurality of horizontal touch electrodes TE_H may be disposed in the second touch metal layer, and the plurality of vertical touch electrodes TE_V may be disposed in the first touch metal layer.

In another example, the plurality of horizontal touch electrodes TE_H may include a plurality of horizontal touch electrodes and a plurality of horizontal bridge electrodes for electrically interconnecting the plurality of horizontal touch electrodes. The plurality of vertical touch electrodes TE_V may include a plurality of vertical touch electrodes and a plurality of vertical bridge electrodes for electrically interconnecting the plurality of vertical touch electrodes. In this implementation, for example, the plurality of horizontal touch electrodes and the plurality of vertical touch electrodes may be disposed in the second touch metal layer, and the plurality of horizontal bridge electrodes and the plurality of vertical bridge electrodes may be disposed in the first touch metal layer.

The roles (functions) of the plurality of horizontal touch electrodes TE_H and the plurality of vertical touch electrodes TE_V may be distinct. For example, the plurality of horizontal touch electrodes TE_H may be driving electrodes (or transmitting electrodes) to which a touch driving signal is applied by the touch driving circuit 220, and the plurality of vertical touch electrodes TE_V may be sensing electrodes (or receiving electrodes) sensed by the touch driving circuit 220. In this example, the plurality of horizontal touch electrodes TE_H may be referred to as driving touch electrodes (or transmitting touch electrodes), and the plurality of vertical touch electrodes TE_V may be referred to as sensing touch electrodes (or receiving touch electrodes).

In another example, the plurality of vertical touch electrodes TE_V may be driving electrodes (or transmitting electrodes) to which a touch driving signal is applied by the touch driving circuit 220, and the plurality of horizontal touch electrodes TE_H may be sensing electrodes (or receiving electrodes) sensed by the touch driving circuit 220. In this example, the plurality of vertical touch electrodes TE_V may be referred to as driving touch electrodes (or transmitting touch electrodes), and the plurality of horizontal touch electrodes TE_H may be referred to as sensing touch electrodes (or receiving touch electrodes).

Referring to FIG. 5, the touch sensor structure may further include a plurality of touch routing lines TL. The plurality of touch routing lines TL may include a plurality of horizontal touch routing lines TL_H and a plurality of vertical touch routing lines TL_V.

The plurality of touch routing lines TL may be disposed in the non-display area NDA. A portion (e.g., a portion connected to a touch electrode) of at least one of the plurality of touch routing lines TL may be located in the display area DA.

The touch sensor structure may further include a plurality of touch pads TP. The plurality of touch pads TP may include a plurality of horizontal touch pads TP_H and a plurality of vertical touch pads TP_V. The plurality of touch pads TP may be disposed in the non-display area NDA.

The plurality of horizontal touch routing lines TL_H may electrically interconnect the plurality of horizontal touch electrodes TE_H and the plurality of horizontal touch pads TP_H. The plurality of vertical touch routing lines TL_V may electrically interconnect the plurality of vertical touch electrodes TE_V and the plurality of vertical touch pads TP_V.

A corresponding one, or corresponding two or more, of the plurality of horizontal touch routing lines TL_H may be connected to each of the plurality of horizontal touch electrodes TE_H. A corresponding one, or corresponding two or more, of the plurality of vertical touch routing lines TL_V may be connected to each of the plurality of vertical touch electrodes TE_V.

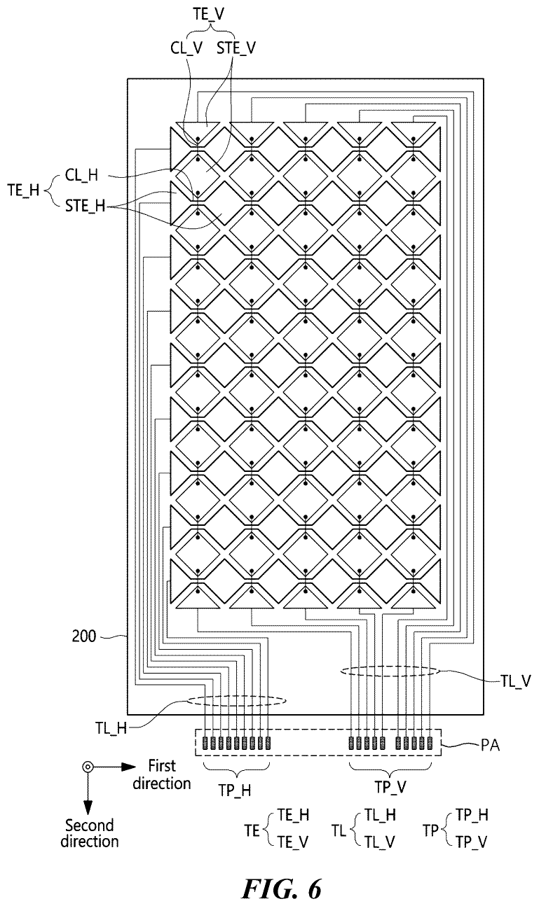

FIG. 6 illustrates another example touch sensor structure included in the display device 100 according to aspects of the present disclosure.

Referring to FIG. 6, in one or more example embodiments, a touch sensor included in the display device 100 may include a plurality of touch electrodes TE. The plurality of touch electrodes TE may include a plurality of horizontal touch electrodes TE_H and a plurality of vertical touch electrodes TE_V.

The plurality of touch electrodes TE may be located in the display area DA and be disposed on the encapsulation layer 200.

Each of the plurality of horizontal touch electrodes TE_H may include two or more horizontal sub-touch electrodes STE_H disposed in the same row (or column) and one or more horizontal bridge electrodes CL_H electrically interconnecting the two or more horizontal sub-touch electrodes STE_H. For example, as in the example of FIG. 6, two or more horizontal sub-touch electrodes STE_H and one or more horizontal bridge electrodes CL_H included in one horizontal touch electrode TE_H may be an integrally formed touch metal (e.g., a second touch metal). In another example, as in the example of FIG. 6, two or more horizontal sub-touch electrodes STE_H may be disposed in a second touch metal layer, and one or more horizontal bridge electrodes CL_H may be disposed in a first touch metal layer.

Each of the plurality of vertical touch electrodes TE_V may include two or more vertical sub-touch electrodes STE_V disposed in the same column (or row) and one or more vertical bridge electrodes CL_V electrically interconnecting the two or more vertical sub-touch electrodes STE_V. For example, two or more vertical sub-touch electrodes STE_V and one or more vertical bridge electrodes CL_V included in one vertical touch electrode TE_V may be an integrally formed touch metal (e.g., a second touch metal). In another example, as in the example of FIG. 6, two or more vertical sub-touch electrodes STE_V may be disposed in a second touch metal layer, and one or more vertical bridge electrodes CL_V may be disposed in a first touch metal layer.

In an area where a horizontal touch electrode TE_H and a vertical touch electrode TE_V intersect each other (which may be referred to as a touch electrode intersection area), a horizontal bridge electrode CL_H and a vertical bridge electrode CL_V may intersect each other.

In the touch electrode intersection area, when the horizontal bridge electrode CL_H and the vertical bridge electrode CL_V intersect, the horizontal bridge electrode CL_H and the vertical bridge electrode CL_V may be needed to be located in different layers.

Accordingly, in order for the plurality of horizontal touch electrodes TE_H and the plurality of vertical touch electrodes TE_V to be disposed to intersect each other, the plurality of horizontal sub-touch electrodes STE_H, the plurality of horizontal bridge electrodes CL_H, the plurality of vertical sub-touch electrodes STE_V, and the plurality of vertical bridge electrodes CL_V may be located in two or more layers.

Referring to FIG. 6, in one or more aspects, the touch sensor structure may further include a plurality of touch routing lines TL. The plurality of touch routing lines TL may include a plurality of horizontal touch routing lines TL_H and a plurality of vertical touch routing lines TL_V.

The plurality of touch routing lines TL may be disposed in the non-display area NDA. A portion (e.g., a portion connected to a touch electrode) of at least one of the plurality of touch routing lines TL may be located in the display area DA.

In one or more aspects, the touch sensor structure may further include a plurality of touch pads TP. The plurality of touch pads TP may include a plurality of horizontal touch pads TP_H and a plurality of vertical touch pads TP_V. The plurality of touch pads TP may be disposed in the non-display area NDA.

Referring to FIG. 6, each of the plurality of horizontal touch electrodes TE_H may be electrically connected to a corresponding horizontal touch pad TP_H via one or more horizontal touch routing lines TL_H. At least one of two horizontal sub-touch electrodes STE_H disposed at the outermost sides among two or more horizontal sub-touch electrodes STE_H included in one horizontal touch electrode TE_H may be electrically connected to a corresponding horizontal touch pad TP_H via a horizontal touch routing line TL_H.

Each of the plurality of vertical touch electrodes TE_V may be electrically connected to a corresponding vertical touch pad TP_V via one or more vertical touch routing lines TL_V. For example, at least one of two vertical sub-touch electrodes STE_V disposed on the outermost sides among two or more vertical sub-touch electrodes STE_V included in one vertical touch electrode TE_V may be electrically connected to a corresponding vertical touch pad TP_V through a vertical touch routing line TL_V.

In one or more aspects, as illustrated in FIG. 6, the plurality of horizontal touch electrodes TE_H and the plurality of vertical touch electrodes TE_V may be disposed on an encapsulation layer 200. The plurality of horizontal sub-touch electrodes STE_H and the plurality of horizontal bridge electrodes CL_H included in the plurality of horizontal touch electrodes TE_H may be disposed on the encapsulation layer 200. The plurality of vertical sub-touch electrodes STE_V and the plurality of vertical bridge electrodes CL_V included in the plurality of vertical touch electrodes TE_V may be disposed on the encapsulation layer 200.

Each of the plurality of horizontal touch routing lines TL_H may be disposed on the encapsulation layer 200, extend outside of the encapsulation layer 200, and be electrically connected to a corresponding one of the plurality of horizontal touch pads TP_H in a pad area PA located in an outward area from the encapsulation layer 200.

Each of the plurality of vertical touch routing lines TL_V may be disposed on the encapsulation layer 200, extend outside of the encapsulation layer 200, and be electrically connected to a corresponding one of the plurality of vertical touch pads TP_V in a pad area PA located in an outward area from the encapsulation layer 200.

The encapsulation layer 200 may be located in the display area DA, and in one or more aspects, may be extended to the non-display area NDA.

As described above, the plurality of touch routing lines TL may be disposed in the non-display area NDA. Therefore, the size of the non-display area NDA may increase because the non-display area NDA needs to include a space where the plurality of touch routing lines TL are disposed.

To address this issue, the size of the non-display area NDA may be reduced by reducing a line width of each of the plurality of touch routing lines TL or reducing a space between the plurality of touch routing lines TL.

However, when the line width of each of the plurality of touch routing lines TL is reduced, an electrical resistance of each of the plurality of touch routing lines TL may increase. Thereby, the signal delay (RC delay) of each of the plurality of touch routing lines TL may increase, and the performance of touch driving and touch sensing may be degraded.

In addition, when the space between the plurality of touch routing lines TL is reduced, a coupling capacitance (which may be also referred to as a coupling noise) between the plurality of touch routing lines TL may increase. Thereby, the signal delay (RC delay) of each of the plurality of touch routing lines TL may increase, and the performance of touch driving and touch sensing may be degraded.

In addition, since respective lengths of the plurality of touch routing lines TL may be different, the electrical characteristics (e.g., resistance, capacitance, etc.) of each of the plurality of touch routing lines TL may be different from each other. Thereby, the performance of touch driving and touch sensing may be degraded.

To address these issues, in one or more aspects, the display device 100 may include a structure capable of reducing the size of the non-display area NDA without a degradation of the performance of touch driving and touch sensing as discussed below.

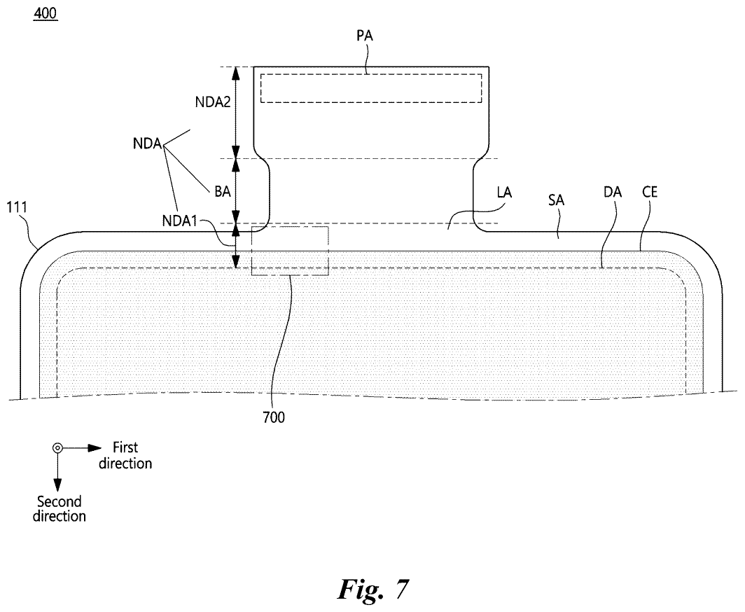

Hereinafter, such an improved touch routing line structure will be described with reference to FIGS. 7 to 14. Discussions for the configurations of FIGS. 7 to 14 are provided with reference to FIGS. 1 to 6 together.

FIG. 7 illustrates an example area 400 included in the display panel 110 according to aspects of the present disclosure.

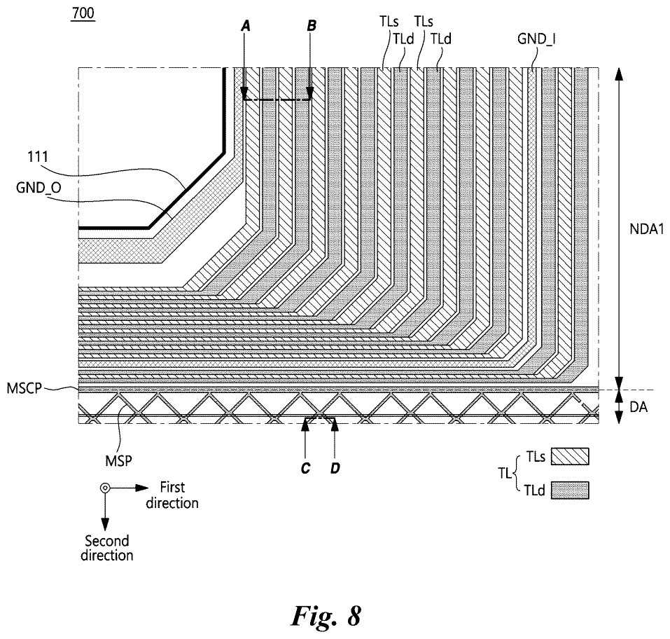

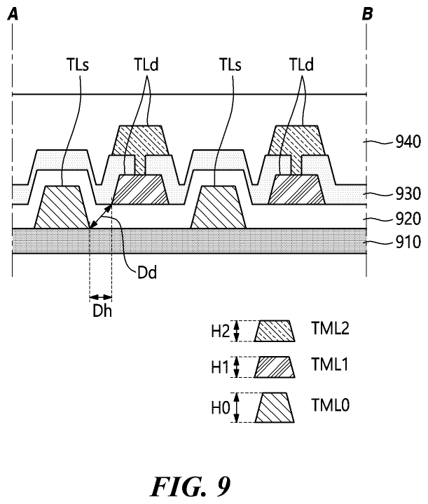

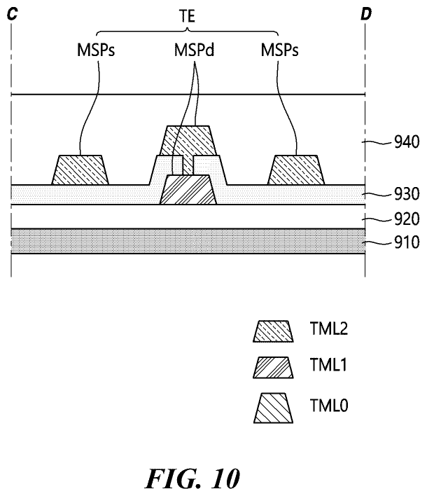

FIG. 7 is an enlarged plan view of a partial area 400 of FIG. 4. FIG. 8 is an enlarged plan view of a partial area 700 of FIG. 7. FIG. 9 is a cross-sectional view taken along line A-B of FIG. 8. FIG. 10 is a cross-sectional view taken along line C-D of FIG. 8.

In one or more example embodiments, the display panel 110 of the display device 100 may include the substrate 111 including the display area DA, and the non-display area NDA adjacent to the display area DA, and a common electrode CE disposed over the substrate 111.

Referring to FIG. 7, the non-display area NDA may include the first non-display area NDA1 adjacent to the display area DA, the second non-display area NDA2 including the pad area PA, and the bending area BA between the first non-display area NDA1 and the second non-display area NDA2.

A plurality of touch electrodes TE may be disposed in the display area DA.

A plurality of touch pads TP may be disposed in the pad area PA included in the second non-display area NDA2.

A plurality of touch routing lines TL may be disposed in the first non-display area NDA1 and the bending area BA. The plurality of touch routing lines TL may electrically interconnect the plurality of touch electrodes TE disposed in the display area DA and the plurality of touch pads TP disposed in the second non-display area NDA2.

The common electrode CE may be disposed in the display area DA, and extend to a portion of the first non-display area NDA1 of the non-display area NDA. An encapsulation layer 200 disposed on the common electrode CE may be disposed to extend further outward than the common electrode CE.

The plurality of touch routing lines TL may be disposed between the display area DA and the second non-display area NDA2 to electrically interconnect the plurality of touch electrodes TE disposed in the display area DA and the plurality of touch pads TP disposed in the second non-display area NDA2.

In one or more aspects, at least one of the plurality of touch routing lines TL may extend to a portion of the display area DA, and at least one of the plurality of touch routing lines TL may extend to a portion of the second non-display area NDA2.

Hereinafter, an example touch routing line structure will be described in more detail.

FIGS. 8 to 10 illustrate example touch routing line structures in the display panel 110 according to aspects of the present disclosure.

FIG. 8 is a plan view of a partial area 700 of FIG. 7. FIG. 9 is a cross-sectional view taken along line A-B of FIG. 8, and illustrates a cross-sectional view of touch routing lines in the first non-display area NDA1. FIG. 10 is a cross-sectional view taken along line C-D of FIG. 8, and illustrates a cross-sectional view of a touch electrode in the display area DA.

Referring to FIGS. 8 and 9, in one or more example embodiments, in a structure where touch routing lines are disposed in the display device 100 or the display panel 110 (i.e., a touch routing line structure), a plurality of touch routing lines TL may be disposed adjacent to each other in the non-display area NDA.

Referring to FIGS. 8 and 9, two adjacent touch routing lines TL among the plurality of touch routing lines TL may include a first type touch routing line TLs including one or more touch metal layers and a second type touch routing line TLd including two or more touch metal layers. For example, first type touch routing lines TLs and the second type touch routing lines TLd may be disposed alternately.

In the touch routing line structure according to one or more aspects, each second type touch routing line TLd may be disposed directly adjacent to each first type touch routing line TLs.

In the touch routing line structure according to one or more aspects, second type touch routing lines TLd may be disposed in a diagonal direction facing upward (or downward) with respect to first type touch routing lines TLs.

Accordingly, even when an interval Dh between each first type touch routing line TLs and each second type touch routing line TLd is short, a substantial separation distance Dd between each first type touch routing line TLs and each second type touch routing line TLd may increase, and thereby, undesired coupling noise between the first type touch routing lines TLs and the second type touch routing lines TLd can be reduced. Accordingly, the quality of touch driving and touch sensing can be improved.

In the touch routing line structure according to one or more aspects, since the substantial separation distance Dd between each first type touch routing line TLs and each second type touch routing line TLd increases, an interval Dh between each first type touch routing line TLs and each second type touch routing line TLd can be made as short as possible within a limited range of coupling noise levels, and thereby, the size of a space where touch routing lines TL are disposed can be reduced as much as possible. By applying these configurations, the display device 100 or the display panel 110 can provide advantages of being made with a narrow bezel without a degradation of the quality of touch driving and touch sensing.

Referring to FIGS. 8 and 9, the touch routing line structure according to one or more aspects may include three touch metal layers (TML1, TML2, and TML0) to form a plurality of touch routing lines TL.

Referring to FIGS. 8 and 9, the three touch metal layers (TML1, TML2, and TML0) may include a first touch metal layer TML1, a second touch metal layer TML2, and a third touch metal layer TML0.

In one or more aspects, referring to FIG. 9, the display panel 110 of the display device 100 may further include a first touch insulating layer 910 disposed on the substrate 111, a second touch insulating layer 920 disposed on the first touch insulating layer 910, a third touch insulating layer 930 disposed on the second touch insulating layer 920, and a fourth touch insulating layer 940 disposed on the third touch insulating layer 930.

Referring to FIG. 9, the first touch metal layer TML1 may be disposed between the second touch insulating layer 920 and the third touch insulating layer 930. The second touch metal layer TML2 may be disposed between the third touch insulating layer 930 and the fourth touch insulating layer 940. The third touch metal layer TML0 may be disposed between the first touch insulating layer 910 and the second touch insulating layer 920.

Referring to FIG. 9, the second touch metal layer TML2 may be electrically connected to the first touch metal layer TML1 through a hole of the third touch insulating layer 930. The third touch metal layer TML0 may be electrically separated from the first touch metal layer TML1 and the second touch metal layer TML2.

Referring to FIG. 9, the second touch metal layer TML2 may be located further away from the substrate 111 than the first touch metal layer TML1.

Referring to FIG. 9, one of the first touch insulating layer 910 and the second touch insulating layer 920 may correspond to the touch buffer layer 351 of FIG. 3, and the other thereof may be an additional insulating layer not included in the touch sensor layer 210 of FIG. 3. The third touch insulating layer 930 may correspond to the touch interlayer insulating layer 352 of FIG. 3. The fourth touch insulating layer 940 may correspond to the touch protection layer 353 of FIG. 3.

In the touch routing line structure according to one or more aspects, the first touch insulating layer 910 may be disposed in both the display area DA and the non-display area NDA.

Referring to FIG. 9, the first touch metal layer TML1 may be a layer in which the first touch metal TM1 of FIG. 3 is disposed, and the second touch metal layer TML2 may be a layer in which the second touch metal TM2 of FIG. 3 is disposed. The third touch metal layer TML0 may be an additional touch metal layer not included in the touch sensor layer 210 of FIG. 3.

In the touch routing line structure according to one or more aspects, among the first to third touch metal layers (TML1, TML2, and TML0), the first touch metal layer TML1 and the second touch metal layer TM2 may be disposed in both the display area DA and the non-display area NDA, and the third touch metal layer TML0 may be disposed only in the non-display area NDA among the display area DA and the non-display area NDA. For example, the third touch metal layer TML0 may be disposed only in the first non-display area NDA1.

In the touch routing line structure according to one or more aspects, among the first to third touch metal layers (TML1, TML2, and TML0), the first touch metal layer TML1 and the second touch metal layer TML2 may be vertically adjacent to each other, and the third touch metal layer TML0 may be located under the first touch metal layer TML1 and the second touch metal layer TML2, or over the first touch metal layer TML1 and the second touch metal layer TML2.

For example, the third touch metal layer TML0 may be located closer to the substrate 111 than the first touch metal layer TML1, or located further away from the substrate 111 than the second touch metal layer TML2. For example, the third touch metal layer TML0 may be located closer to an encapsulation layer 200 than the first touch metal layer TML1 or located further away from the encapsulation layer 200 than the second touch metal layer TML2.

Referring to FIGS. 8 and 9, in the touch routing line structure according to one or more aspects, two or more touch metal layers (e.g., the first touch metal layer TML1 and the second touch metal layer TML2) included in a second type touch routing line TLd and one or more touch metal layers (e.g., the third touch metal layer TML0) included in a first type touch routing line TLs may be different metal layers.

Therefore, in the touch routing line structure according to one or more aspects, the second touch insulating layer 920 may be disposed between two or more touch metal layers (e.g., the first touch metal layer TML1 and the second touch metal layer TML2) included in the second type touch routing line TLd and one or more touch metal layers (e.g., the third touch metal layer TML0) included in the first type touch routing line TLs.

Referring to FIGS. 8 and 9, in the touch routing line structure according to one or more aspects, the number of one or more touch metal layers included in the first type touch routing line TLs may be less than the number of two or more touch metal layers included in the second type touch routing line TLd. For example, second type touch routing lines TLd may be touch routing lines that are directly adjacent to first type touch routing lines TLs.

Referring to FIGS. 8 and 9, in the touch routing line structure according to one or more aspects, a difference between a first type touch routing line TLs and a second type touch routing line TLd, which are disposed adjacent to each other, may be clear in the first non-display area NDA1.

For example, in the touch routing line structure according to one or more aspects, in the first non-display area NDA1, each second type touch routing line TLd may include a portion TL4a including the first touch metal layer TML1 and the second touch metal layer TML2, which are electrically connected to each other, and each first type touch routing line TLs may include a portion TL1a including the third touch metal layer TML0. For example, the third touch metal layer TML0 may be different from the first touch metal layer TML1 and the second touch metal layer TML2.

In the touch routing line structure according to one or more aspects, a portion disposed in the first non-display area NDA1 among portions of each first type touch routing line TLs may be a single line portion (which may be referred to as a single layer line portion) including the third touch metal layer TML0. A portion disposed in the first non-display area NDA1 among portions of each second type touch routing line TLd may be a double line portion (which may be referred to as a double layer line portion) including the first touch metal layer TML1 and the second touch metal layer TML2.

Since a portion disposed in the first non-display area NDA1 among portions of each first type touch routing line TLs is a single line portion and a portion disposed in the first non-display area NDA1 among portions of each second type touch routing line TLd is a double line portion, the resistance of each first type touch routing line TLs may be greater than the resistance of each second type touch routing line TLd.

Therefore, in the touch routing line structure according to one or more aspects, in order to reduce a resistance difference between the first type touch routing lines TLs and the second type touch routing lines TLd, one or more touch metal layers included in each first type touch routing line TLs may be formed thicker than each of two or more touch metal layers included in each second type touch routing line TLd.

By applying this configuration, even when a portion disposed in the first non-display area NDA1 among portions of each first type touch routing lines TLs includes a smaller number of touch metal layers than a portion disposed in the first non-display area NDA1 among portions of each second type touch routing line TLd, a difference in resistance between the first type touch routing lines TLs and the second type touch routing lines TLd can be significantly reduced.

For example, a thickness H0 of the third touch metal layer TML0 included in a first type touch routing line TLs may be greater than a thickness H1 of the first touch metal layer TML1 and a thickness H2 of the second touch metal layer TML2 included in a second type touch routing line TLd. For example, the third touch metal layer TML0 may be thicker than the first touch metal layer TML1 and the second touch metal layer TML2.

Accordingly, even when a portion disposed in the first non-display area NDA1 among portions of each first type touch routing line TLs is a single line portion and a portion disposed in the first non-display area NDA1 among portions of each second type touch routing line TLd is a double line portion, a difference in resistance between the first type touch routing lines TLs and the second type touch routing lines TLd can be significantly reduced.

Referring to FIGS. 9 and 10, in the touch routing line structure according to one or more aspects, a plurality of touch electrodes TEs disposed in the display area DA may include a touch metal layer different from one or more touch metal layers (for example, the third touch metal layer TML0) included in each first type touch routing line TLs, and may include a touch metal layer that is the same as at least one of two or more touch metal layers (for example, the first touch metal layer TML1 and the second touch metal layer TML2) included in each second type touch routing line TLd.

For example, a plurality of touch electrodes TE may include a touch metal layer different from the third touch metal layer TML0 included in the first type touch routing lines TLs, and may include the same touch metal layer as at least one of the first touch metal layer TML1 and the second touch metal layer TML2 included in the second type touch routing lines TLd. For example, each of the plurality of touch electrodes TE may include one or two touch metal layers among the first touch metal layer TML1, the second touch metal layer TML2, and the third touch metal layer TML0.

For example, the plurality of touch electrodes TE may include the second touch metal layer TML2. In another example, the plurality of touch electrodes TE may include the first touch metal layer TML1 and the second touch metal layer TML2.

Referring to FIG. 8, each touch electrode TE may be configured to have a mesh with a plurality of openings (hereinafter, which may be referred to as a mesh pattern MSP). Each of the openings formed by the mesh pattern MSP may overlap with a light emitting area of a corresponding light emitting element ED. For example, each of the openings formed by the mesh pattern MSP may serve as an optical path through which light emitted from the light emitting element ED passes.

Referring to FIG. 8, each touch electrode TE may further include a mesh connection pattern MSCP for connecting edges of the mesh pattern MSP, in addition to the mesh pattern MSP.

For example, referring to FIGS. 8 and 10, each of the plurality of touch electrodes TE has a structure where a touch metal layer located farther away from the substrate 111 among the first touch metal layer TML1 and the second touch metal layer TML2 is configured to have a mesh with a plurality of openings.

For example, the second touch metal layer TML2 included in each touch electrode TE may be configured to have a mesh with a plurality of openings. Accordingly, each touch electrode TE may have the plurality of openings. Each of the plurality of openings may overlap with a light emitting area of a corresponding light emitting element ED in the vertical direction. For example, the plurality of openings may serve as paths through which light emitted from light emitting elements ED passes.

In another example, each touch electrode TE may be configured to have a mesh pattern MSP, and the mesh pattern MPS may include the first touch metal layer TML1 and the second touch metal layer TML2.

For example, the mesh pattern MSP may include a double mesh pattern MSPd including the first touch metal layer TML1 and the second touch metal layer TML2, which are electrically connected to each other, and a single mesh pattern MSPs including one of the first touch metal layer TML1 and the second touch metal layer TML2 (e.g., the second touch metal layer TML2 in the configuration of FIG. 10). In an area of one touch electrode TE, the double mesh pattern MSPd and the single mesh pattern MSPs may be electrically connected to each other. However, aspects of the present disclosure are not limited thereto.

The double mesh pattern MSPd may be a configuration where two adjacent sub-touch electrodes are connected by a bridge electrode within one touch electrode TE. In the double electrode pattern MSPd, the first touch metal layer TML1 may be a bridge electrode (see FIGS. 3 and 6).

Referring to FIG. 8, in one or more aspects, the display panel 110 of the display device 100 may further include at least one ground line among a first ground line GND_I located in the non-display area NDA and disposed between a plurality of touch routing lines TL, and a second ground line GND_O located in the non-display area NDA and disposed between an outermost touch routing line TL among the plurality of touch routing lines TL and an edge of the substrate 111.

For example, the at least one ground line may include at least one of the touch metal layers (TML1, TML2, and TML0) included in each of the plurality of touch routing lines TL.

For example, in the touch routing line structure according to one or more aspects, both the first ground line GND_I and the second ground line GND_O may be located in the non-display area NDA.

For example, the first ground line GND_I may have a double line structure in which the first touch metal layer TML1 and the second touch metal layer TML2 are electrically connected.

For example, the second ground line GND_O may have a double line structure in which the first touch metal layer TML1 and the second touch metal layer TML2 are electrically connected.

For example, the first ground line GND_I may be disposed between a plurality of touch routing lines TL. For example, touch routing lines TL disposed on one side of the first ground line GND_I may be driving touch routing lines to which a touch driving signal is applied during touch driving, and touch routing lines TL disposed on the other side of the first ground line GND_I may be sensing touch routing lines sensed by the touch driving circuit 220. Accordingly, the driving touch routing lines and the sensing touch routing lines may be shielded by the first ground line GND_I. Thereby, undesired influence between the driving touch routing lines and the sensing touch routing lines can be reduced, and the quality of the touch driving and touch sensing can be improved.

Referring to FIG. 8, each of the plurality of touch routing lines TL may include a first direction line portion extending in a first direction and a second direction line portion extending in a second direction. For example, the first direction may be a direction in which gate lines GL extend, and the second direction may be a direction in which data lines DL extend. In another example, the first direction may be the horizontal direction, and the second direction may be the vertical direction.

Referring to FIG. 8, each of the plurality of touch routing lines TL may include a portion located in the second non-display area NDA2, a portion located in the bending area BA, and a portion located in the first non-display area NDA1. In each of the plurality of touch routing lines TL, the portion located in the second non-display area NDA2 and the portion located in the bending area BA may extend in the second direction, and the portion located in the first non-display area NDA1 may extend in the second direction, and then be bent and extend in the first direction.

Referring to FIG. 8, the first non-display area NDA1 may include a link area LA allowing each of the plurality of touch routing lines TL to extend in the second direction, and a peripheral area SA allowing each of the plurality of touch routing lines TL to extend in the first direction and located adjacent to the display area DA. An available area of the peripheral area SA for allowing lines to be disposed may be smaller compared to the link area LA. For example, a space in which touch routing lines TL can be disposed in the peripheral area SA may be much less than a space in which touch routing lines TL can be disposed in the link area LA.

Therefore, in the touch routing line structure according to one or more aspects, each of the plurality of touch routing lines TL may include a first direction line portion extending in the first direction and a second direction line portion extending in the second direction, and the first direction line portion may have a line width smaller than the second direction line portion.

For examples, the non-display area NDA may include the first non-display area NDA1 adjacent to the display area DA, the second non-display area NDA2 in which a plurality of touch pads TP are disposed, and the bending area BA between the first non-display area NDA1 and the second non-display area NDA2. The bending area BA may be an area in which the substrate 110 is bent. The first non-display area NDA1 and the second non-display area NDA2 may represent areas on both sides of the bending area BA. The first non-display area NDA1 may include the link area LA connected to the bending area BA and the peripheral area SA adjacent to the display area DA.

Each of the plurality of touch routing lines TL may include a portion located in the link area LA and a portion located in the peripheral area SA. The portion of the touch routing line TL located in the link area LA may extend in the second direction, and the portion of the touch routing line TL located in the peripheral area SA may extend in the first direction.

In the touch routing line structure according to one or more aspects, a width of the portion of the touch routing line TL located in the peripheral area SA may be less than a width of the portion of the touch routing line TL located in the link area LA.

To realize a narrow bezel design, it may be desired to reduce the size of the peripheral area SA. Among portions of each of a plurality of touch routing lines TL located in the non-display area NDA, by designing a line width of a portion located in the peripheral area SA to be smaller than a line width of a portion located in the link area LA, the size of the peripheral area SA can be significantly reduced, and thereby, the implementation of a narrow bezel design can be facilitated.

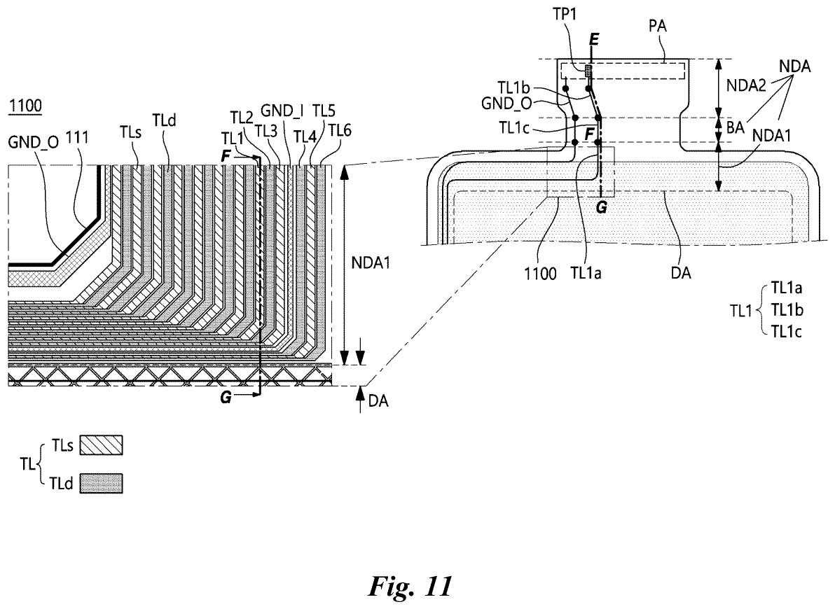

Hereinafter, the touch routing line structure described above will be described in more detail with reference to FIGS. 11 to 14.

FIGS. 11 to 14 are plan views and cross-sectional views for explaining example respective structures of first type touch routing lines and second type touch routing lines in the display panel 110 according to aspects of the present disclosure.

Referring to FIGS. 11 to 14, a plurality of touch routing lines TL disposed in the non-display area NDA may include first to sixth touch routing lines (TL1 to TL6).

Among the first to sixth touch routing lines (TL1 to TL6), the first touch routing line TL1, the third touch routing line TL3, and the fifth touch routing line TL5 may be first type touch routing lines TLs, and the second touch routing line TL2, the fourth touch routing line TL4, and the sixth touch routing line TL6 may be second type touch routing lines TLd.

A first ground line GND_I may be disposed between the third touch routing line TL3 and the fourth touch routing line TL4, and a second ground line GND_O may be disposed further outward than an outermost touch routing line TL and disposed adjacent to an edge of the substrate 111.

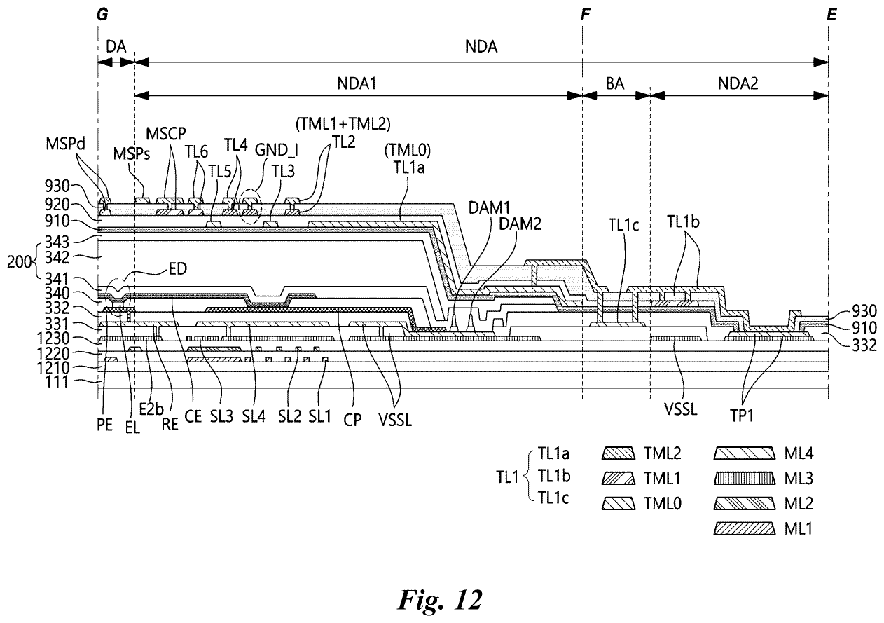

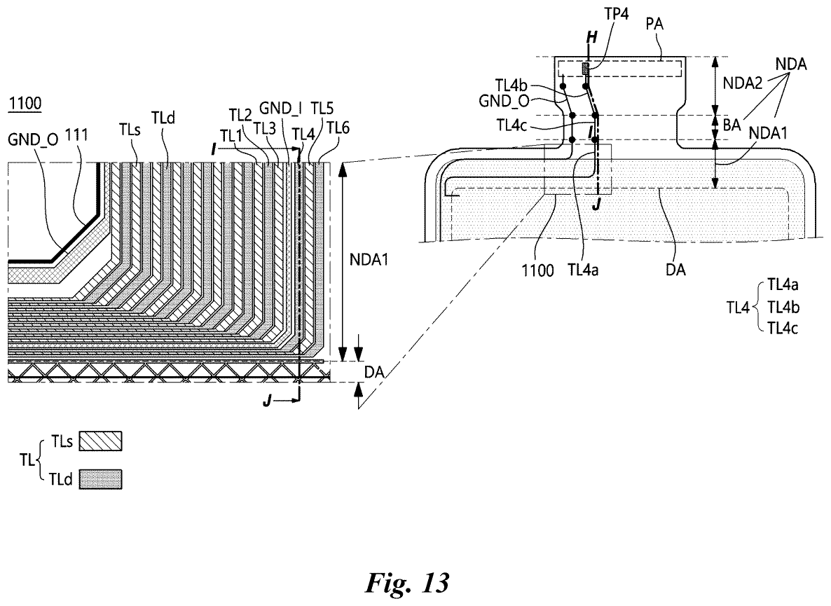

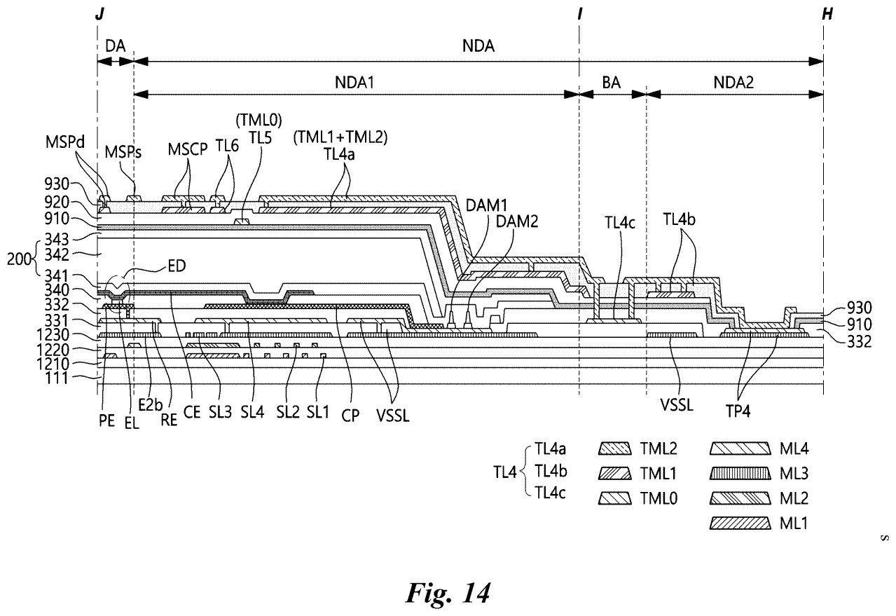

Referring to FIGS. 11 and 12, the structure of the first type touch routing lines TLs is described, and referring to FIGS. 13 and 14, the structure of second type touch routing lines TLd is described.

Referring to FIGS. 11 and 12, the first touch routing line TL1, which is the first type touch routing line TLs, may interconnect a first touch pad TP1 disposed in a pad area PA in the second non-display area NDA2 and a first touch electrode TE disposed in the display area DA. For example, the first touch routing line TL1 may be disposed across the second non-display area NDA2, the bending area BA, and the first non-display area NDA1.

Referring to FIGS. 11 and 12, a touch routing line structure related to the first touch routing line TL1 is described with reference to a cross-sectional view (FIG. 12) taken along line E-G connecting location E outside of the first touch pad TP1, location F in a boundary between the bending area BA and the first non-display area NDA1, and location G in the display area DA.

Referring to FIGS. 13 and 14, the fourth touch routing line TL4, which is the second type touch routing line TLd, may interconnect a fourth touch pad TP4 located in the pad area PA in the second non-display area NDA2 and a fourth touch electrode TE located in the display area DA. For example, the fourth touch routing line TL4 may be disposed across the second non-display area NDA2, the bending area BA, and the first non-display area NDA1.

Referring to FIGS. 13 and 14, a touch routing line structure related to the fourth touch routing line TL4 is described with reference to a cross-sectional view (FIG. 14) taken along line H-J connecting location H outside of the fourth touch pad TP4, location I in a boundary between the bending area BA and the first non-display area NDA1, and location J in the display area DA.

Referring to FIGS. 12 and 14, in one or more aspects, the display panel 110 of the display device 100 may include a substrate 11, a light emitting element ED disposed on the substrate 111, an encapsulation layer 200 on the light emitting element ED, and a touch sensor layer on the encapsulation layer 200.

The light emitting element ED may include a pixel electrode PE disposed on the substrate 111 and located in the display area DA, an intermediate layer EL disposed on the pixel electrode PE, and a common electrode CE disposed on the intermediate layer EL and allowing a first common voltage VSS to be applied.

The encapsulation layer 200 may be disposed on the common electrode CE and may have an inclined surface. The encapsulation layer 200 may include a first encapsulation layer 341, a second encapsulation layer 342, and a third encapsulation layer 343, but aspects of the present disclosure are not limited thereto. For example, the first encapsulation layer 341 and the third encapsulation layer 343 may be inorganic encapsulation layers, and the second encapsulation layer 342 may include an organic encapsulation layer. However, aspects of the present disclosure are not limited thereto.

Referring to FIGS. 12 and 14, transistors and capacitors included in a corresponding subpixel circuit SPC of each subpixel SP may be disposed between the substrate 111 and a corresponding light emitting element ED. Several signal lines (SL1, SL2, SL3, and/or SL4) for driving each subpixel circuit SPC may be disposed between the substrate 111 and a corresponding light emitting element ED.

For example, a first insulating layer 1210 may be disposed on the substrate 111, a second insulating layer 1220 may be disposed on the first insulating layer 1210, and a third insulating layer 1230 may be disposed on the second insulating layer 1220.

For example, the first insulating layer 1210 may include the first buffer layer 311 and the first gate insulating layer 312 of FIG. 3. The second insulating layer 1220 may include the first interlayer insulating layer 313 of FIG. 3. The third insulating layer 1230 may include the second buffer layer 321, the second gate insulating layer 322, and the second interlayer insulating layer 323 of FIG. 3.

Referring to FIG. 12 and FIG. 14, a first planarization layer 331 may be disposed on the third insulating layer 1230. A second planarization layer 332 may be disposed on the first planarization layer 331. A bank 340 may be disposed on the second planarization layer 332.

The common electrode CE may be disposed on the bank 340. The encapsulation layer 200 may be disposed on the common electrode CE, and the encapsulation layer 200 may include the first encapsulation layer 341, the second encapsulation layer 342, and the third encapsulation layer 343.

Referring to FIG. 12 and FIG. 14, a touch sensor layer 210 may be disposed on the encapsulation layer 200. The touch sensor layer 210 may include a first touch insulating layer 910 on the encapsulation layer 200, a third touch metal layer TML0 on the first touch insulating layer 910, a second touch insulating layer 920 on the third touch metal layer TML0, a first touch metal layer TML1 on the second touch insulating layer 920, a third touch insulating layer 930 on the first touch metal layer TML1, and a second touch metal layer TML2 on the third touch insulating layer 930. The touch sensor layer 210 may further include a fourth touch insulating layer 940 on the second touch metal layer TML2, and the fourth touch insulating layer 940 may be disposed in the same configuration as the touch protection layer 353 of FIG. 3.

Referring to FIGS. 12 and 14, in one or more aspects, the display panel 110 may include a first metal layer ML1 disposed between the first insulating layer 1210 and the second insulating layer 1220, a second metal layer ML2 disposed between the second insulating layer 1220 and the third insulating layer 1230, a third metal layer ML3 disposed between the third insulating layer 1230 and the first planarization layer 331, and a fourth metal layer ML4 disposed between the first planarization layer 331 and the second planarization layer 332.

For example, the fourth metal layer ML4 may be a second source-drain metal layer. The third metal layer ML3 may be a first source-drain metal layer. The second metal layer ML2 may be a metal layer in which a second capacitor electrode CAPE2 is disposed. The first metal layer ML1 may be a first gate metal layer.

Referring to FIG. 12 and FIG. 14, at least one of the first touch insulating layer 910, the second touch insulating layer 920, the third touch insulating layer 930, and the fourth touch insulating layer 940 may be disposed to extend to the second non-display area NDA2, and include an opening overlapping with at least a portion of at least one touch pad (TP1 and/or TP4). The at least one touch pad (TP1 and/or TP4) and at least one touch routing line (TL1 and/or TL4) may be connected through the opening of at least one of the first touch insulating layer 910, the second touch insulating layer 920, the third touch insulating layer 930, and the fourth touch insulating layer 940.

For example, the second planarization layer 332 may be disposed to extend to the second non-display area NDA2, and include an opening overlapping with at least a portion of the at least one touch pad (TP1 and/or TP4). Through the opening of the second planarization layer 332, the at least one touch pad (TP1 and/or TP4) and the at least one touch pad (TP1 and/or TP4) may be connected to each other.

In the examples of FIGS. 12 and 14, the second planarization layer 332, the first touch insulating layer 910, and the third touch insulating layer 930 may be disposed to extend to the second non-display area NDA2, and include respective openings overlapping with at least a portion of the at least one touch pad (TP1 and/or TP4). The at least one touch pad (TP1 and/or TP4) and the at least one touch pad (TP1 and/or TP4) may be connected to each other through the respective openings (which may be referred to as a contact hole) of the second planarization layer 332, the first touch insulating layer 910, and the third touch insulating layer 930.

Referring to FIG. 12 and FIG. 14, transistors, capacitors, and several signal lines included in the display panel 110 may be disposed in at least one metal layer among the first to fourth metal layers (ML1, ML2, ML3, and ML4).

For example, a plurality of signal lines (SL1, SL2, SL3, and SL4) to which signals different from a common voltage VSS are applied may be disposed in at least one metal layer among the first to fourth metal layers (ML1, ML2, ML3, and ML4). The plurality of signal lines (SL1, SL2, SL3, and SL4) may be lines for delivering signals related to display driving. For example, the plurality of signal lines may include at least one of at least one second common voltage line VDDL for delivering a second common voltage VDD, at least one data line DL for delivering a data voltage VDATA, at least one gate line GL for delivering a gate signal, and at least one gate driving-related signal line for delivering several gate driving-related signals supplied to the gate driving circuit 130. For example, the at least one gate driving-related signals may include at least one of a gate clock signal, a high-level gate voltage, a low-level gate voltage, a gate driving power supply voltage, and the like.

Referring to FIGS. 12 and 14, the common electrode CE may be disposed in the display area DA, and in one or more aspects, be extended to a portion of the first non-display area NDA1. For example, an area where the common electrode CE is disposed may include the display area DA and further include a portion of the first non-display area NDA1.

Referring to FIGS. 12 and 14, at least a portion of at least one of the plurality of touch routing lines TL may overlap with the common electrode CE. One or more of the plurality of touch routing lines TL may overlap with at least one or more of the plurality of signal lines (SL1, SL2, SL3, and SL4).

The common electrode CE may be disposed between one or more of the plurality of touch routing lines TL and at least one or more of the plurality of signal lines (SL1, SL2, SL3, and SL4). For example, the common electrode CE may extend between one or more of the plurality of touch routing lines TL and at least one or more of the plurality of signal lines (SL1, SL2, SL3, and SL4).

Accordingly, the formation of coupling capacitance (coupling noise) between one or more of the plurality of touch routing lines TL and one or more of the plurality of signal lines (SL1, SL2, SL3, and SL4) can be prevented. The formation of coupling capacitance (coupling noise) between one or more of the plurality of touch routing lines TL and one or more of the plurality of signal lines (SL1, SL2, SL3, and SL4) may mean that a change in voltage on one or more of the plurality of signal lines (SL1, SL2, SL3, and SL4) may cause an undesired change in voltage on one or more of the plurality of touch routing lines TL.

Therefore, as the common electrode CE is disposed to extend between one or more of the plurality of touch routing lines TL and one or more of the plurality of signal lines (SL1, SL2, SL3, and SL4), the common electrode CE can reduce or block a negative influence (display noise) on one or more of the plurality of touch routing lines TL by driving (e.g., a resulted change in voltage) of one or more of the plurality of signal lines (SL1, SL2, SL3, and SL4).

Referring to FIGS. 12 and 14, one or more of the plurality of touch routing lines TL may include at least a portion not overlapping with the plurality of signal lines (SL1, SL2, SL3, and SL4).

For example, the first touch routing line TL1 may include a portion overlapping with the common electrode CE and a portion not overlapping with the common electrode CE. Among portions of the first touch routing line TL1, the portion overlapping with the common electrode CE may overlap with at least one of the plurality of signal lines (SL1, SL2, SL3, and SL4), and the portion not overlapping with the common electrode CE may not overlap with the plurality of signal lines (SL1, SL2, SL3, and SL4).

For example, the first touch routing line TL1 may include a portion overlapping with at least one of the plurality of signal lines (SL1, SL2, SL3, and SL4) and a portion not overlapping with the plurality of signal lines (SL1, SL2, SL3, and SL4). Among portions of the first touch routing line TL1, the portion overlapping with at least one of the plurality of signal lines (SL1, SL2, SL3, and SL4) may overlap with the common electrode CE, and the portion not overlapping with the plurality of signal lines (SL1, SL2, SL3, and SL4) may not overlap with the common electrode CE.

Referring to FIG. 12 and FIG. 14, the common electrode CE may be disposed to extend from the display area DA to a portion of the first non-display area NDA1. The encapsulation layer 200 may be disposed to extend further outward than the common electrode CE.

One or more mesh patterns (MSPd and/or MSPs) forming each of a plurality of touch electrodes TE may be disposed on the encapsulation layer 200. In one or more aspects, at least one mesh connection pattern MSCP for connecting mesh patterns (MSPd and/or MSPs) may also be disposed on the encapsulation layer 200.

One or more mesh patterns (MSPd and/or MSPs) forming each of the plurality of touch electrodes TE may be disposed in the display area DA. One or more of mesh patterns (MSPd and/or MSPs) or at least a corresponding portion of each of the one or more mesh patterns may extend to the first non-display area NDA1. At least one mesh connection pattern MSCP included in each of the plurality of touch electrodes TE may be disposed in the display area DA. At least a portion of the mesh connection pattern MSCP may be disposed in the first non-display area NDA1.

For example, one or more mesh patterns (MSPd and/or MSPs) forming each of the plurality of touch electrodes TE may be configured with at least one of the first touch metal layer TML1 and the second touch metal layer TML2. At least one mesh connection pattern MSCP included in each of the plurality of touch electrodes TE may be configured with at least one of the first touch metal layer TML1 and the second touch metal layer TML2.

At least a portion of at least one of the plurality of touch routing lines TL may be disposed on the encapsulation layer 200 and overlap with the common electrode CE.

Referring to FIGS. 11 to 14, the first to sixth touch routing lines (TL1 to TL6) and the first ground line GND_I may be present on line E-F-G.

Referring to FIGS. 11 to 14, the first touch routing line TL1, the third touch routing line TL3, and the fifth touch routing line TL5 may be first type touch routing lines TLs configured with the third touch metal layer TML3 in the first non-display area NDA1. The second touch routing line TL2, the fourth touch routing line TL4, and the sixth touch routing line TL6 may be second type touch routing lines TLd configured with the first touch metal layer TML1 and the second touch metal layer TML2, which are electrically connected in the first non-display area NDA1.

Referring to FIG. 12, the first touch routing line TL1 may include a first portion TL1a disposed in the first non-display area NDA1, a second portion TL1b disposed in the second non-display area NDA2, and a third portion TL1c disposed in the bending area BA. The third portion TL1c may interconnect the first portion TL1a and the second portion TL1b.

Referring to FIG. 12, the first portion TL1a of the first touch routing line TL1 may be a single line portion and include the third touch metal layer TML0.

The second portion TL1b of the first touch routing line TL1 may include at least one of the first touch metal layer TML1 and the second touch metal layer TML2.

The third portion TL1c of the first touch routing line TL1 may include a metal layer different from the first to third touch metal layers (TML1, TML2, and TML0). For example, the metal layer included in the third portion TL1c of the first touch routing line TL1 may be the same as a metal layer in which an electrode or line for display driving is disposed. For example, the metal layer included in the third portion TL1c of the first touch routing line TL1 may include a metal layer in which at least one of the first to fourth metal layers (ML1 to ML4) or the pixel electrode PE is disposed.

The first touch pad TP1 may be electrically connected to the second portion TL1b of the first touch routing line TL1 and may include a metal layer different from the first to third touch metal layers (TML1, TML2, and TML0). For example, the metal layer included in the first touch pad TP1 may be the same as a metal layer in which an electrode or line for display driving is disposed. For example, the metal layer included in the first touch pad TP1 may include a metal layer in which at least one of the third metal layer ML3 and the fourth metal layer ML4 or the pixel electrode PE is disposed.

Referring to FIG. 14, the fourth touch routing line TL4 may include a first portion TL4a disposed in the first non-display area NDA1, a second portion TL4b disposed in the second non-display area NDA2, and a third portion TL4c disposed in the bending area BA. The third portion TL4c may interconnect the first portion TL4a and the second portion TL4b.

Referring to FIG. 14, the first portion TL4a of the fourth touch routing line TL4 may be a double line portion and include the first touch metal layer TML1 and the second touch metal layer TML2, which are electrically connected to, and overlap with, each other.

The second portion TL4b of the fourth touch routing line TL4 may include at least one of the first touch metal layer TML1 and the second touch metal layer TML2.

The third portion TL4c of the fourth touch routing line TL4 may include a metal layer different from the first to third touch metal layers (TML1, TML2, and TML0). For example, the metal layer included in the third portion TL4c of the fourth touch routing line TL4 may be the same as a metal layer in which one or more electrodes or lines for display driving are disposed. For example, the metal layer included in the third portion TL4c of the fourth touch routing line TL4 may include a metal layer in which at least one of the first to fourth metal layers (ML1 to ML4) or the pixel electrode PE is disposed.

The fourth touch pad TP4 may be electrically connected to the second portion TL4b of the fourth touch routing line TL4 and may include a metal layer different from the first to third touch metal layers (TML1, TML2, and TML0). For example, the metal layer included in the fourth touch pad TP4 may be the same as a metal layer in which one or more electrodes or lines for display driving are disposed. For example, the metal layer included in the fourth touch pad TP4 may include a metal layer in which at least one of the third metal layer ML3 and the fourth metal layer ML4 or the pixel electrode PE is disposed.

Referring to FIG. 12, the first portion TL1a of the first touch routing line TL1, which is the first type touch routing line TLs, may be disposed along an inclined surface of the encapsulation layer 200, and include the third touch metal layer TML0 on the inclined surface of the encapsulation layer 200. For example, the inclined surface of the encapsulation layer 200 may mean an inclined surface formed on an outer side of the second encapsulation layer 342, which is an organic layer included in the encapsulation layer 200.

The first portion TL1a of the first touch routing line TL1, which is the first type touch routing line TLs, may extend along the inclined surface of the encapsulation layer 200 and extend over an upper portion of at least one dam (DAM1 and/or DAM2).

For example, the first portion TL1a of the first touch routing line TL1, which is the first type touch routing line TLs, may be connected to the third portion TL1c of the first touch routing line TL1 through at least one of the first touch metal layer TML1 and the second touch metal layer TML2.

For example, the third portion TL1c of the first touch routing line TL1 may be connected to the second portion TL1b of the first touch routing line TL1.

For example, the second portion TL1b of the first touch routing line TL1 may include the second touch metal layer TML2. In another example, the second portion TL1b of the first touch routing line TL1 may be formed by electrically connecting the first touch metal layer TML1 and the second touch metal layer TML2.

For example, the second portion TL1b of the first touch routing line TL1 may be electrically connected to the first touch pad TP1 including at least one of the third and fourth metal layers (ML3 and ML4) through respective openings (which may be referred to as a contact hole) of the second planarization layer 332, the first touch insulating layer 910, and the third touch insulating layer 930.

Referring to FIG. 14, the first portion TL4a of the fourth touch routing line TL4, which is the second type touch routing line TLd, may be disposed along the inclined surface of the encapsulation layer 200, and include the first touch metal layer TML1 and the second touch metal layer TML2 on the inclined surface of the encapsulation layer 200.

The first portion TL4a of the fourth touch routing line TL4, which is the second type touch routing line TLd, may extend along the inclined surface of the encapsulation layer 200 and extend over an upper portion of at least one dam (DAM1 and/or DAM2).

For example, the first portion TL4a of the fourth touch routing line TL4, which is the second type touch routing line TLd, may be connected to the third portion TL4c of the fourth touch routing line TL4 through at least one of the first touch metal layer TML1 and the second touch metal layer TML2.

For example, the third portion TL4c of the fourth touch routing line TL4 may be connected to the second portion TL4b of the fourth touch routing line TL4.

For example, the second portion TL4b of the fourth touch routing line TL4 may include the second touch metal layer TML2. In another example, the second portion TL4b of the fourth touch routing line TL4 may be formed by an electrical connection of the first touch metal layer and the second touch metal layer.

For example, the second portion TL4b of the fourth touch routing line TL4 may be electrically connected to the fourth touch pad TP4 including at least one of the third and fourth metal layers (ML3 and ML4) through respective openings (which may be referred to as a contact hole) of the second planarization layer 332, the first touch insulating layer 910, and the third touch insulating layer 930.

Referring to FIGS. 12 and 14, in one or more aspects, the display panel 110 of the display device 100 may further include a first common voltage line VSSL to which a first common voltage VSS is applied, and a connection pattern CP for connecting the common electrode CE and the first common voltage line VSSL. For example, the connection pattern CP may include the same material as the pixel electrode PE.

Referring to FIGS. 12 and 14, in one or more aspects, the display panel 110 of the display device 100 may further include at least one signal line (SL1, SL2, SL3, and/or SL4) to which a signal different from the first common voltage VSS is applied.

Referring to FIGS. 12 and 14, at least one touch routing line TL among the plurality of touch routing lines TL may overlap with the at least one signal line (SL1, SL2, SL3, and/or SL4). The common electrode CE may extend between the at least one touch routing line TL and the at least one signal line (SL1, SL2, SL3, and/or SL4).

Referring to FIG. 12, in the bending area BA, the first touch routing line TL1, which is the first type touch routing lines TLs, may include the third portion TL1c including a metal layer different from the third touch metal layer TML0.

Referring to FIG. 14, in the bending area BA, the fourth touch routing line TL4, which is the second type touch routing line TLd, may include the third portion TL4c (which may also be referred to as a third bending portion TL4c) including a metal layer different from the first touch metal layer TML1 and the second touch metal layer TML2.

Referring to FIG. 12, in the second non-display area NDA2, the first touch routing line TL1, which is the first type touch routing line TLs, may include the second portion TL1b including the first touch metal layer TML1 and the second touch metal layer TML2.

Referring to FIG. 14, in the second non-display area NDA2, the fourth touch routing line TL4, which is the second type touch routing line TLd, may include the second portion TL4b (which may also be referred to as a second bending portion TL4b) including a metal layer different from the first touch metal layer TML1 and the second touch metal layer TML2.

Referring to FIG. 12 and FIG. 14, each of a plurality of touch pads (TP1 and TP4) may include a metal layer different from the first touch metal layer TML1 and the second touch metal layer TML2.

As described above, in the touch routing line structure according to one or more aspects, the plurality of touch routing lines TL may include one or more first type touch routing lines TLs including at least one touch metal layer (e.g., the third touch metal layer TML0) not included in a plurality of touch electrodes TE.

In the touch routing line structure according to one or more aspects, the plurality of touch routing lines TL may further include one or more second type touch routing lines TLd including at least one touch metal layer (e.g., the third touch metal layer TML0) included in a plurality of touch electrodes TE.

The second type touch routing lines TLd may include a double line portion including the first touch metal layer TML1 and the second touch metal layer TML2, which are electrically connected to each other. The first touch metal layer TML1 and the second touch metal layer TML2 may be included in the plurality of touch electrodes TE.

The first type touch routing lines TLs may include a single portion including the third touch metal layer TML0. For example, the third touch metal layer TML0 may not be included in a plurality of touch electrodes TE.

For example, the third touch metal layer TML0 may be different from the first touch metal layer TML1 and the second touch metal layer TML2. For example, a location of the third touch metal layer TML0 may be different from respective locations of the first touch metal layer TML1 and the second touch metal layer TML2.

For example, the third touch metal layer TML0 may be located closer to the substrate 111 than the first touch metal layer TML1 and the second touch metal layer TML2. In another example, the third touch metal layer TML0 may be located further away from the substrate 111 than the first touch metal layer TML1 and the second touch metal layer TML2.

The double line portion of the second type touch routing lines TLd may be disposed adjacent to the single portion of the first type touch routing lines TLs.

The double line portion of the second type touch routing lines TLd may be disposed in an upward diagonal direction with respect to the single line portion of the first type touch routing lines TLs. Accordingly, an interval between touch routing lines TL can be reduced without a degradation of the performance of touch driving and touch sensing, and a size of the first non-display area NDA1 can be reduced.

As in the second type touch routing lines TLd, when all portions of each touch routing line TL are formed with a double line structure, the resistance of each touch routing line TL can be reduced, but a thickness of the touch sensor layer may be increased. Thereby, the process of forming the touch sensor layer can also be complicated.

As in the second type touch routing lines TLd, when all touch routing lines TL are formed with a double line structure, it may be difficult to reduce an interval between two adjacent touch routing lines TL, and thereby, it may be difficult or impossible to make the display device 100 or the display panel 110 to have a narrow bezel.

In contrast, in the touch routing line structure according to one or more aspects, as two touch routing lines TL adjacent to each other in the first non-display area NDA, which is the most important for implementing a narrow bezel, are formed with the single line structure and the double line structure, an interval between two adjacent touch routing lines TL in the first non-display area NDA can be significantly reduced. Accordingly, the implementation of a narrow bezel can be realized.

Further, in the touch routing line structure according to one or more aspects, as two touch routing lines TL disposed adjacent to each other in the first non-display area NDA are located diagonally from each other, an interval between the two touch routing lines TL adjacent to each other in the first non-display area NDA can be significantly reduced. Accordingly, the implementation of a narrow bezel can be realized.

Further, in the touch routing line structure according to one or more aspects, among the two touch routing lines TL disposed adjacent to each other in the first non-display area NDA, a thickness of the third touch metal layer TML0 included in the first type touch routing lines TLs having the single line portion may be greater than a thickness of each of the first touch metal layer TML and the second touch metal layer TML2 included in second type touch routing lines TLd having the double line portion.

Thereby, a difference in resistance between the second type touch routing lines TLd having the double line portion and the first type touch routing lines TLs having the single portion can be reduced. Therefore, the quality of touch driving and touch sensing can be improved without an increase of the bezel size.

The examples, aspects, and embodiments described above will be briefly described as follows.

According to the one or more example embodiments described herein, a display device can be provided that includes a substrate including a display area and a non-display area adjacent to the display area, a plurality of touch electrodes disposed on the substrate and located in the display area, a plurality of touch pads disposed on the substrate and located in the non-display area, and a plurality of touch routing lines disposed on the substrate and electrically interconnecting the plurality of touch electrodes and the plurality of touch pads.

In one or more aspects, two adjacent touch routing lines among the plurality of touch routing lines may include a first type touch routing line including one or more touch metal layers and a second type touch routing line including two or more touch metal layers. In one or more aspects, the number of the one or more touch metal layers included in the first type touch routing line may be less than the number of the two or more touch metal layers included in the second type touch routing line.

In one or more aspects, the display device may further include a touch insulating layer disposed between the one or more touch metal layers included in the first type touch routing line and the two or more touch metal layers included in the second type touch routing line.

In one or more aspects, each of the one or more touch metal layers included in the first type touch routing line may have a thickness greater than each of the two or more touch metal layers included in the second type touch routing line.

In one or more aspects, the plurality of touch electrodes may include a touch metal layer different from the one or more touch metal layers included in the first type touch routing line, and include a same touch metal layer as at least one of the two or more touch metal layers included in the second type touch routing line.

In one or more aspects, the non-display area may include a first non-display area adjacent to the display area, a second non-display area including a pad area where the plurality of touch pads are disposed, and a bending area between the first non-display area and the second non-display area.

In one or more aspects, in the first non-display area, the second type touch routing line may include a portion including a first touch metal layer and a second touch metal layer, which are electrically connected to each other, and the first type touch routing line may include a portion including a third touch metal layer. In one or more aspects, the third touch metal layer may be different from the first touch metal layer and the second touch metal layer.

In one or more aspects, the second touch metal layer may be located further away from the substrate than the first touch metal layer. In one or more aspects, the third touch metal layer may be located closer to the substrate than the first touch metal layer or further away from the substrate than the second touch metal layer.

In one or more aspects, the third touch metal layer may be thicker than the first touch metal layer and thicker than the second touch metal layer.

In one or more aspects, each of the plurality of touch electrodes may include one or two touch metal layers among a first touch metal layer, a second touch metal layer, and a third touch metal layer.

In one or more aspects, each of the plurality of touch electrodes may have a structure where a touch metal layer located further away from the substrate among the first touch metal layer and the second touch metal layer is configured to have a mesh.

In one or more aspects, the first touch metal layer and the second touch metal layer may be disposed in both the display area and the non-display area, and the third touch metal layer may be disposed only in the non-display area among the display area and the non-display area.

In one or more aspects, the display device may further include a first touch insulating layer disposed on the substrate, a second touch insulating layer disposed on the first touch insulating layer, a third touch insulating layer disposed on the second touch insulating layer, and a fourth touch insulating layer disposed on the third touch insulating layer.

In one or more aspects, the first touch metal layer may be disposed between the second touch insulating layer and the third touch insulating layer. In one or more aspects, the second touch metal layer may be disposed between the third touch insulating layer and the fourth touch insulating layer. In one or more aspects, the third touch metal layer may be disposed between the first touch insulating layer and the second touch insulating layer.

In one or more aspects, the second touch metal layer may be electrically connected to the first touch metal layer through a hole of the third touch insulating layer. In one or more aspects, the third touch metal layer may be electrically separated from the first touch metal layer and the second touch metal layer.

In one or more aspects, the display device may further include a pixel electrode disposed on the substrate and located in the display area, an intermediate layer disposed on the pixel electrode, a common electrode disposed on the intermediate layer and allowing a first common voltage to be applied, and an encapsulation layer disposed on the common electrode and having an inclined surface.

In one or more aspects, the common electrode may be disposed to extend from the display area to a portion of the first non-display area. In one or more aspects, the encapsulation layer may be disposed to extend further outward than the common electrode.

In one or more aspects, the plurality of touch electrodes may be disposed on the encapsulation layer.

In one or more aspects, at least a portion of at least one of the plurality of touch routing lines may be disposed on the encapsulation layer and overlap with the common electrode.

In one or more aspects, the first type touch routing line may be disposed along the inclined surface, and include the third touch metal layer on the inclined surface. In one or more aspects, the second type touch routing line may be disposed along the inclined surface, and include the first touch metal layer and the second touch metal layer on the inclined surface.

In one or more aspects, the display device may further include a first common voltage line to which the first common voltage is applied, and a connection pattern interconnecting the common electrode and the first common voltage line. In one or more aspects, the connection pattern may include a same material as the pixel electrode.

In one or more aspects, the display device may further include at least one signal line to which a signal different from the first common voltage is applied.

In one or more aspects, at least one touch routing line among the plurality of touch routing lines may overlap with the at least one signal line. In one or more aspects, the common electrode may extend between the at least one touch routing line and the at least one signal line.

In one or more aspects, in the bending area, the first type touch routing line may include a portion including a metal layer different from the third touch metal layer, and the second type touch routing line may include a bending portion including a metal layer different from the first touch metal layer and the second touch metal layer.

In one or more aspects, in the second non-display area, the first type touch routing line may include a portion including the first touch metal layer and the second touch metal layer, and the second type touch routing line may include a bending portion including a metal layer different from the first touch metal layer and the second touch metal layer.

In one or more aspects, each of the plurality of touch pads may include a metal layer different from the first touch metal layer and the second touch metal layer.

In one or more aspects, the display device may further include at least one of a first ground line located in the non-display area and disposed between the plurality of touch routing lines, and a second ground line located in the non-display area and disposed between an outermost touch routing line among the plurality of touch routing lines and an edge of the substrate.

In one or more aspects, the at least one ground line may include at least one of a plurality of touch metal layers included in the plurality of touch routing wires.

In one or more aspects, the non-display area may include a first non-display area adjacent to the display area, a second non-display area in which the plurality of touch pads are disposed, and a bending area between the first non-display area and the second non-display area.

In one or more aspects, the first non-display area may include a link area connected to the bending area and a peripheral area adjacent to the display area. In one or more aspects, each of the plurality of touch routing lines may include a portion disposed in the link area and a portion disposed in the peripheral area. In one or more aspects, a line width of the portion disposed in the peripheral area may be less than a line width of the portion disposed in the link area.

According to the one or more example embodiments described herein, a display device can be provided that includes a substrate including a display area and a non-display area adjacent to the display area, a plurality of touch electrodes disposed on the substrate and located in the display area, and a plurality of touch routing lines disposed on the substrate and electrically connected to the plurality of touch electrodes.

In one or more aspects, the plurality of touch routing lines may include a first type touch routing line including a touch metal layer not included in the plurality of touch electrodes. In one or more aspects, the first type touch routing line may include a touch metal layer not included in the plurality of touch electrodes.

In one or more aspects, the plurality of touch routing lines may further include a second type touch routing line comprising a touch metal layer included in the plurality of touch electrodes. In one or more aspects, the second type touch routing line may include a double line portion comprising a first touch metal layer and a second touch metal layer, which are electrically connected to each other. In one or more aspects, the first touch metal layer and the second touch metal layer may be included in the plurality of touch electrodes.

In one or more aspects, the first type touch routing line may include a single line portion including a third touch metal layer, and the third touch metal layer may not be included in the plurality of touch electrodes. In one or more aspects, the third touch metal layer may be different from the first touch metal layer and the second touch metal layer.

In one or more aspects, the double line portion may be disposed adjacent to the single line portion, and the double line portion may be disposed in a diagonal direction facing upward or downward with respect to the single line portion.

In one or more aspects, a thickness of the third touch metal layer may be greater than a thickness of each of the first touch metal layer and the second touch metal layer.

In one or more aspects, the display device may further include a light emitting element, an encapsulation layer on the light emitting element, a first touch insulating layer disposed on the encapsulation layer, a second touch insulating layer disposed on the first touch insulating layer, a third touch insulating layer disposed on the second touch insulating layer, and a fourth touch insulating layer disposed on the third touch insulating layer.

In one or more aspects, the first touch metal layer may be disposed between the second touch insulating layer and the third touch insulating layer, the second touch metal layer may be disposed between the third touch insulating layer and the fourth touch insulating layer, the third touch metal layer may be disposed between the first touch insulating layer and the second touch insulating layer.

In one or more aspects, the second touch metal layer may be electrically connected to the first touch metal layer through a hole of the third touch insulating layer. In one or more aspects, the third touch metal layer may be electrically separated from the first touch metal layer and the second touch metal layer.

As discussed above, according to the one or more aspects described herein, a display device may be provided that includes touch routing lines disposed in a structure capable of enabling the display device to have a narrow bezel.

According to the one or more aspects described herein, a display device may be provided that includes touch routing lines disposed in a structure capable of enabling the display device to have a narrow bezel and improving the quality of touch driving and touch sensing.

According to the one or more aspects described herein, a display device may be provided that includes touch routing lines disposed in a structure capable of reducing a difference in resistance between two adjacent touch routing lines while reducing an interval between two adjacent touch routing lines.

According to the one or more aspects described herein, a display device may be provided that includes touch routing lines disposed in a structure capable of reducing coupling noise between touch channels.

According to the one or more aspects described herein, a display device may be provided that includes touch routing lines disposed in a structure capable of reducing a difference in resistance between touch channels.

According to the one or more aspects described herein, a display device may be provided that includes touch routing lines disposed in a structure of being robust to display noise.

According to the one or more aspects described herein, a display device may be provided that is capable of reducing the size of a bezel of the display device, and thereby, capable of meeting size requirements on the design of the display device and helping the display device be lighter.

The examples, aspects, and embodiments of the present disclosure described above have been described for illustrative purposes, and those skilled in the art will appreciate that various modifications, additions and substitutions are possible, without departing from the scope and spirit of the disclosure as disclosed in the accompanying claims. Therefore, the technical features of the present disclosure described in the above description or shown in the accompanying drawings should be interpreted as illustrative only and should not be taken as limiting the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate comprising a display area and a non-display area adjacent to the display area;
a plurality of touch electrodes on the substrate and located in the display area;
a plurality of touch pads on the substrate and located in the non-display area; and
a plurality of touch routing lines on the substrate and electrically interconnecting the plurality of touch electrodes and the plurality of touch pads,
wherein two adjacent touch routing lines among the plurality of touch routing lines comprises a first type touch routing line comprising one or more touch metal layers, and a second type touch routing line comprising two or more touch metal layers, and
wherein a number of the one or more touch metal layers included in the first type touch routing line is less than a number of the two or more touch metal layers included in the second type touch routing line.

2. The display device of claim 1, further comprising a touch insulating layer between the one or more touch metal layers included in the first type touch routing line and the two or more touch metal layers included in the second type touch routing line.

3. The display device of claim 1, wherein each of the one or more touch metal layers included in the first type touch routing line has a thickness greater than each of the two or more touch metal layers included in the second type touch routing line.

4. The display device of claim 1, wherein the plurality of touch electrodes comprises at least one touch metal layer not included in the first type touch routing line, and at least one touch metal layer that is the same as a touch metal layer included in the second type touch routing line.

5. The display device of claim 1, wherein the non-display area comprises a first non-display area adjacent to the display area, a second non-display area comprising a pad area where the plurality of touch pads is disposed, and a bending area between the first non-display area and the second non-display area,
wherein in the first non-display area, the second type touch routing line comprises a portion comprising a first touch metal layer and a second touch metal layer, the first touch metal layer and the second touch metal layer being electrically connected to each other, and
wherein the first type touch routing line comprises a portion comprising a third touch metal layer, and the third touch metal layer is different from the first touch metal layer and the second touch metal layer.

6. The display device of claim 5, wherein the second touch metal layer is located further away from the substrate than the first touch metal layer, and
wherein the third touch metal layer is located closer to the substrate than the first touch metal layer or further away from the substrate than the second touch metal layer.

7. The display device of claim 5, wherein the third touch metal layer is thicker than the first touch metal layer and thicker than the second touch metal layer.

8. The display device of claim 5, wherein the first touch metal layer and the second touch metal layer are disposed in both the display area and the non-display area, and the third touch metal layer is disposed only in the non-display area among the display area and the non-display area.

9. The display device of claim 5, wherein each of the plurality of touch electrodes has a structure where a touch metal layer located further away from the substrate among the first touch metal layer and the second touch metal layer is configured to have a mesh.

10. The display device of claim 5, further comprising:
a first touch insulating layer on the substrate;
a second touch insulating layer on the first touch insulating layer;
a third touch insulating layer on the second touch insulating layer; and
a fourth touch insulating layer on the third touch insulating layer,
wherein the first touch metal layer is between the second touch insulating layer and the third touch insulating layer, the second touch metal layer is between the third touch insulating layer and the fourth touch insulating layer, the third touch metal layer is between the first touch insulating layer and the second touch insulating layer, and
wherein the second touch metal layer is electrically connected to the first touch metal layer through a hole of the third touch insulating layer, and the third touch metal layer is electrically separated from the first touch metal layer and the second touch metal layer.

11. The display device of claim 5, further comprising:
a pixel electrode on the substrate and located in the display area;
an intermediate layer on the pixel electrode;
a common electrode on the intermediate layer and allowing a first common voltage to be applied; and
an encapsulation layer on the common electrode and having an inclined surface,
wherein the common electrode is disposed to extend from the display area to a portion of the first non-display area, and the encapsulation layer is disposed to extend further outward than the common electrode, and
wherein the plurality of touch electrodes is disposed on the encapsulation layer, and at least a portion of at least one of the plurality of touch routing lines is on the encapsulation layer and overlaps with the common electrode.

12. The display device of claim 11, wherein the first type touch routing line is disposed along the inclined surface, and comprises the third touch metal layer on the inclined surface, and the second type touch routing line is disposed along the inclined surface, and includes the first touch metal layer and the second touch metal layer on the inclined surface.

13. The display device of claim 11, further comprising:
a first common voltage line to which the first common voltage is applied; and
a connection pattern interconnecting the common electrode and the first common voltage line,
wherein the connection pattern comprises a same material as the pixel electrode.

14. The display device of claim 11, further comprising at least one signal line to which a signal different from the first common voltage is applied,
wherein at least one touch routing line among the plurality of touch routing lines overlaps with the at least one signal line, and the common electrode extends between the at least one touch routing line and the at least one signal line.

15. The display device of claim 5, wherein in the bending area, the first type touch routing line comprises a portion comprising a metal layer different from the third touch metal layer, and the second type touch routing line comprises a bending portion comprising a metal layer different from the first touch metal layer and the second touch metal layer.

16. The display device of claim 5, wherein in the second non-display area, the first type touch routing line comprises a portion comprising the first touch metal layer and the second touch metal layer, and the second type touch routing line comprises a bending portion comprising a metal layer different from the first touch metal layer and the second touch metal layer.

17. The display device of claim 5, wherein each of the plurality of touch pads comprises a metal layer different from the first touch metal layer and the second touch metal layer.

18. The display device of claim 1, further comprising at least one of a first ground line located in the non-display area and disposed between the plurality of touch routing lines, and a second ground line located in the non-display area and disposed between an outermost touch routing line among the plurality of touch routing lines and an edge of the substrate, and
wherein the at least one ground line comprises at least one of a plurality of touch metal layers included in the plurality of touch routing wires.

19. The display device of claim 1, wherein the non-display area comprises a first non-display area adjacent to the display area, a second non-display area in which the plurality of touch pads are disposed, and a bending area between the first non-display area and the second non-display area,
wherein the first non-display area comprises a link area connected to the bending area and a peripheral area adjacent to the display area,
wherein each of the plurality of touch routing lines comprises a portion disposed in the link area and a portion disposed in the peripheral area, and
wherein a line width of the portion disposed in the peripheral area is less than a line width of the portion disposed in the link area.

20. A display device comprising:
a substrate comprising a display area and a non-display area adjacent to the display area;
a plurality of touch electrodes on the substrate and located in the display area; and
a plurality of touch routing lines on the substrate and electrically connected to the plurality of touch electrodes,
wherein the plurality of touch routing lines comprises a first type touch routing line comprising a touch metal layer not included in the plurality of touch electrodes.

21. The display device of claim 20, wherein the plurality of touch routing lines further comprises a second type touch routing line comprising a touch metal layer included in the plurality of touch electrodes.

22. The display device of claim 21, wherein the second type touch routing line comprises a double line portion comprising a first touch metal layer and a second touch metal layer, which are electrically connected to each other, and the first touch metal layer and the second touch metal layer are included in the plurality of touch electrodes, and
wherein the first type touch routing line comprises a single line portion comprising a third touch metal layer, and
wherein the third touch metal layer is not included in the plurality of touch electrodes and is different from the first touch metal layer and the second touch metal layer.

23. The display device of claim 22, wherein the double line portion is disposed adjacent to the single line portion, and the double line portion is disposed in a diagonal direction facing upward or downward with respect to the single line portion.

24. The display device of claim 22, wherein a thickness of the third touch metal layer is greater than a thickness of each of the first touch metal layer and the second touch metal layer.

25. The display device of claim 22, further comprising:
a light emitting element;
an encapsulation layer on the light emitting element;
a first touch insulating layer on the encapsulation layer;
a second touch insulating layer on the first touch insulating layer;
a third touch insulating layer on the second touch insulating layer; and
a fourth touch insulating layer on the third touch insulating layer,
wherein the first touch metal layer is between the second touch insulating layer and the third touch insulating layer, the second touch metal layer is between the third touch insulating layer and the fourth touch insulating layer, the third touch metal layer is between the first touch insulating layer and the second touch insulating layer, and
wherein the second touch metal layer is electrically connected to the first touch metal layer through a hole of the third touch insulating layer, and the third touch metal layer is electrically separated from the first touch metal layer and the second touch metal layer.
